(19) United States
(12) Patent Application Publication
(10) Pub. No.: US 2026/0033124 A1
(43) Pub. Date: Jan. 29, 2026

(54) COMPOUND FOR ORGANIC ELECTROLUMINESCENT DEVICE AND ORGANIC ELECTROLUMINESCENT DEVICE COMPRISING SAME

(71) Applicant: SHIJIAZHUANG CHENGZHI YONGHUA DISPLAY MATERIAL CO., LTD., Shijiazhuang (CN)

(72) Inventors: Hualong DING, Shijiazhuang (CN); Jianchao WANG, Shijiazhuang (CN); Hui ZHANG, Shijiazhuang (CN); Hao ZHANG, Shijiazhuang (CN)

(73) Assignee: SHIJIAZHUANG CHENGZHI YONGHUA DISPLAY MATERIAL CO, LTD., Shijiazhuang (CN)

(21) Appl. No.: 19/346,039

(22) Filed: Sep. 30, 2025

(30) Foreign Application Priority Data
Apr. 18, 2025 (CN) 202510487505.3

(51) Int. Cl. H10K 50/11; H10K 50/15; H10K 50/19; H10K 85/60

(52) U.S. Cl. CPC H10K 50/11; H10K 50/15; H10K 50/19; H10K 85/626; H10K 85/633; H10K 85/654; H10K 85/656; H10K 85/6572; H10K 85/6574; H10K 85/658

(57) ABSTRACT

The present invention provides a compound for an organic electroluminescent device and an organic electroluminescent device comprising the compound. The compound has a structure represented by formula I. The compound has a multi-substituted dehydrogenated fused-ring structure with a plurality of substituents, wherein the substituents contain a fluorobenzodioxole structure. The unique fluorobenzodioxole structure has not only good thermal stability but also stable electron-withdrawing ability. The unique fluorobenzodioxole structure is connected to a multi-substituted dehydrogenated fused-ring parent nucleus, so that the organic compound of the present invention has superior hole doping ability, can improve the hole injection ability in the hole injection layer when used for preparing an organic electroluminescent device, reduce the voltage of the device, and improve the efficiency and lifetime of the device.

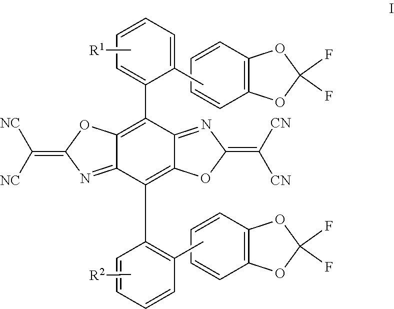

### TECHNICAL FIELD

The present invention belongs to the technical field of OLEDs and in particular comprises a compound for an organic electroluminescent device and an organic electroluminescent device comprising the compound.

### BACKGROUND ART

Organic electronic devices include, but are not limited to, the following categories: organic light-emitting diodes, organic field effect transistors, organic light-emitting transistors, organic photovoltaic devices, dye-sensitized solar cells, organic optical detectors, organic photoreceptors, organic field effect devices, light-emitting electrochemical cells, organic laser diodes, and organic electroluminescent devices.

In 1987, Tang and Van Slyke of Eastman Kodak reported a two-layer organic electroluminescent device, comprising an arylamine hole transport layer and a tris(8-hydroxyquinoline)aluminum layer as an electron transport layer and a light-emitting layer (Applied Physics Letters, 1987,51(12): 913-915). Once a bias voltage is applied to the device, green light is emitted from the device. This invention laid the foundation for the development of modern organic light-emitting diodes. The most advanced OLEDs may comprise a plurality of layers, e.g., charge injection and transport layers, charge and exciton barrier layers, and one or more light-emitting layers between a cathode and an anode. Since OLEDs are self-luminous solid-state devices, they provide great potential for display and lighting applications. In addition, the inherent characteristics of organic materials, such as their flexibility, can make them very suitable for special applications, such as the manufacture of flexible substrates.

OLEDs can be divided into three main types according to their luminous mechanisms. The fluorescent OLED first invented by Tang and van Slyke only uses singlet state light emission. The triplet state generated in a device will be wasted by means of non-radiation attenuation, limiting the internal quantum efficiency thereof to 25%. This efficiency bottleneck has severely hindered the early commercialization process of OLEDs. Until 1997, a phosphorescent OLED reported by Forrest and Thompson made a breakthrough. This technology successfully captured singlet-state and triplet-state excitons by introducing a complex containing a heavy metal as a light emitter and achieved 100% IQE. The high efficiency characteristic of the phosphorescent OLED directly promotes the commercialized development of organic light-emitting diodes. In recent years, a thermally activated delayed fluorescent material developed by the Adachi's team further expands the scope of high-efficiency OLEDs. This type of organic light emitter has a relatively small singlet-triplet energy gap, which enables regeneration singlet-state excitons from triplet-state excitons through reverse intersystem crossing and also achieves nearly 100% IQE.

OLEDs can also be divided into small molecule OLED materials and polymer OLED materials according to the form of the material. Small molecule OLED materials: Non-polymeric organic or organometallic materials are used, which are characterized by accurate molecular structures. Even if the molecular weight is relatively large, it is still classified as small molecules as long as the structure is clear (such as dendritic macromolecules). Polymer OLED materials: They mainly include conjugated polymers and non-conjugated polymers with luminescent side groups. It is worth noting that some small molecule OLEDs may undergo post-polymerization during the manufacturing process and are thus converted into polymer OLEDs.

The manufacturing method for OLEDs mainly depends on the type of the material used. Manufacturing methods for small molecule OLED materials include: traditional methods including vacuum thermal evaporation (high purity deposition, suitable for insoluble materials); and solution methods. If the small molecules are soluble in solvents, solution methods (such as spin coating and inkjet printing) can also be used. The manufacturing methods for polymer OLED materials usually involve manufacturing by solution methods, including spin coating, inkjet printing, nozzle printing, etc., as their polymeric properties render them challenging for vacuum evaporation.

The luminescent colors of OLEDs can be regulated and controlled by the structural design of the luminescent material, and the device can achieve the target spectrum by means of a single-layer or multi-layer light-emitting structure. At present, green, yellow, and red phosphorescent OLEDs have been successfully commercialized; however, blue phosphorescent devices still face challenges such as blue unsaturation, short lifetime and high working voltage. Therefore, commercial full-color OLED displays usually employ a hybrid strategy, which combines blue fluorescent materials with phosphorescent yellow/red materials. At present, the phosphorescent OLEDs still have the problem of a significant drop in efficiency at high brightness. The industry is looking forward to developing new luminescent materials with more saturated luminescent spectrum, higher efficiency and longer lifetime.

p-Type doping materials (PD materials) are materials that play a critically important role in OLED devices. These materials are mainly used in combination with hole transport materials to form hole injection layers or p-type charge generation layers. Typically, when using a PD material to prepare an OLED display panel, the process involves co-evaporation and thermal sublimation of the PD material and a hole transport material, followed by deposition onto a surface of a substrate to form a thin film, onto which other functional layers and light-emitting layers are then gradually evaporated. Therefore, excellent PD materials are required to have good thermal stability and withstand a long-term high-temperature environment during the evaporation process while ensuring the performance of the evaporated device. Good device performance also requires PD materials to have a superior hole injection ability. Therefore, the PD material is required to have a relatively low LUMO energy level to achieve good matching with the HOMO energy level of the hole transport material, thus improving the hole injection ability. Studying PD materials that can exhibit both superior thermal stability and superior doping capability is the key to the development of such materials.

### SUMMARY OF THE INVENTION

The present invention aims to provide a range of organic compounds having dehydrogenated fused-ring structures with specific substituents so as to solve at least some of the above-mentioned problems. These organic compounds can be used as charge transport materials, charge injection materials, or similar materials in organic electroluminescent devices. Due to the unique structural design, these newly developed organic compounds exhibit superior hole injection ability and relatively high thermal stability. These organic compounds can endow organic electroluminescent devices with excellent performance, such as reduced device voltage and improved device efficiency and lifetime.

To this end, a first aspect of the present invention provides a compound for an organic electroluminescent device. The general structural formula of the compound is as represented by formula I:

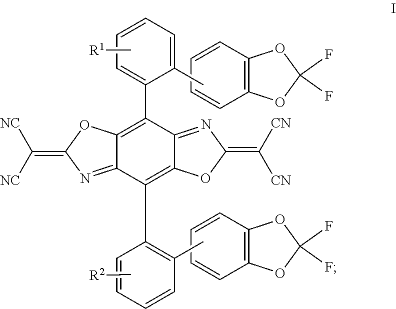

in formula I,
R¹ and R² respectively represent substituents on benzene rings and are selected from monosubstitution or polysubstitution, and when R¹ and R² refer to polysubstitution, the plurality of substituents can be the same or different;
R¹ and R² are, at each occurrence, each independently selected from any one of or any combination of some of hydrogen, deuterium, fluoro, and CF₃; and
hydrogens in the compound represented by formula I can be each independently replaced by deuterium.

Furthermore, the compound has a structure represented by formula I-1 or formula I-2:

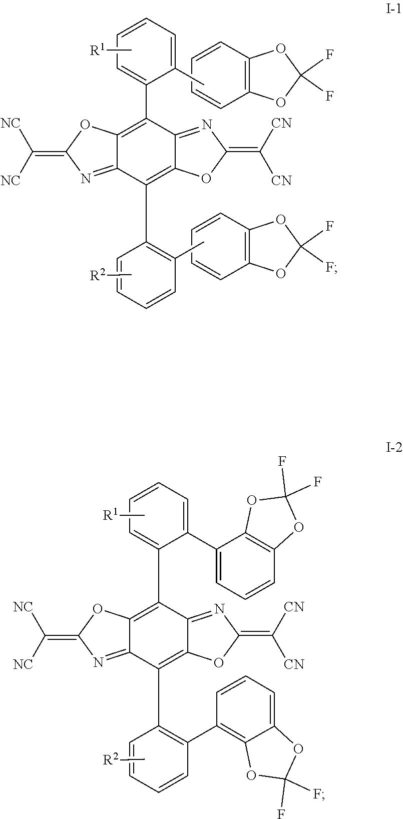

wherein
R¹ and R² respectively represent substituents on benzene rings and are selected from monosubstitution, polysubstitution, or unsubstitution, and when R¹ and R² refer to polysubstitution, the plurality of substituents can be the same or different;
R¹ and R² are, at each occurrence, each independently selected from any one of or any combination of some of hydrogen, deuterium, fluoro, and CF₃; and
hydrogens in the compounds represented by formula I-1 and formula I-2 can be each independently replaced by deuterium.

Furthermore, R¹ and R² represent the same group.

Furthermore, the compound is selected from one of the following structures:

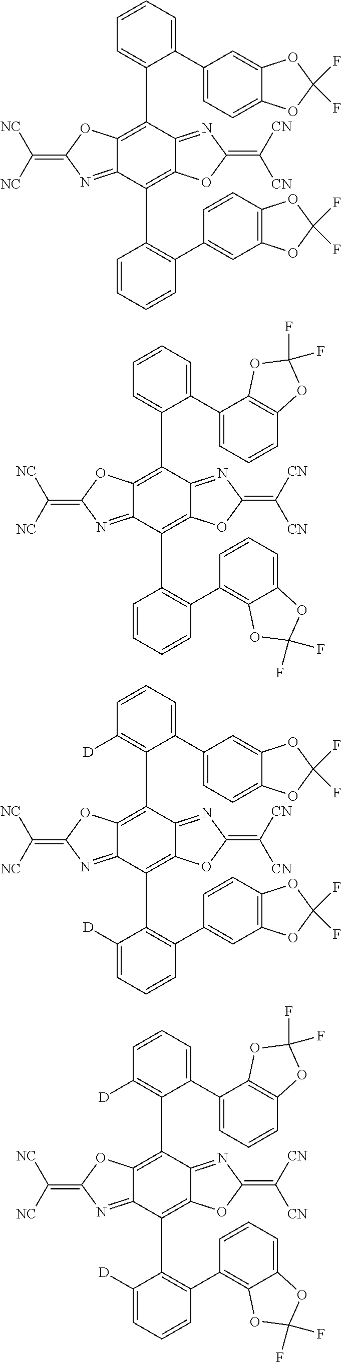

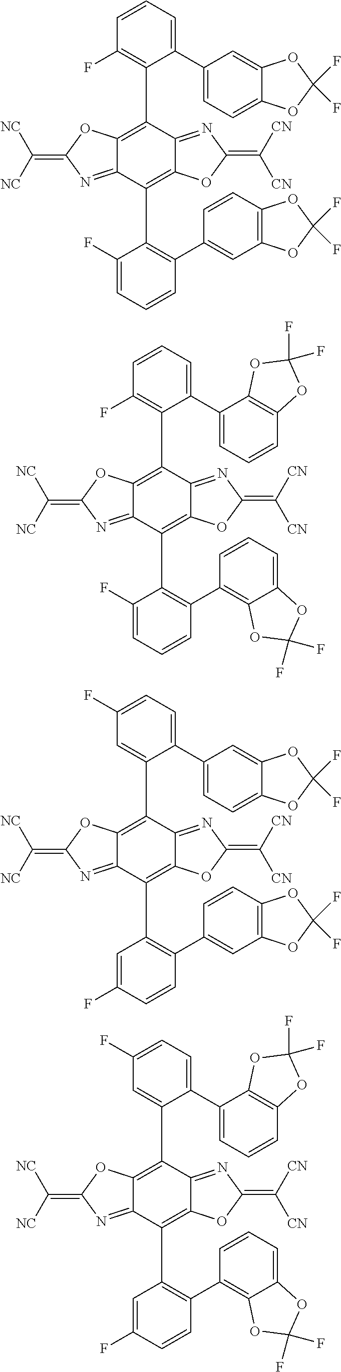

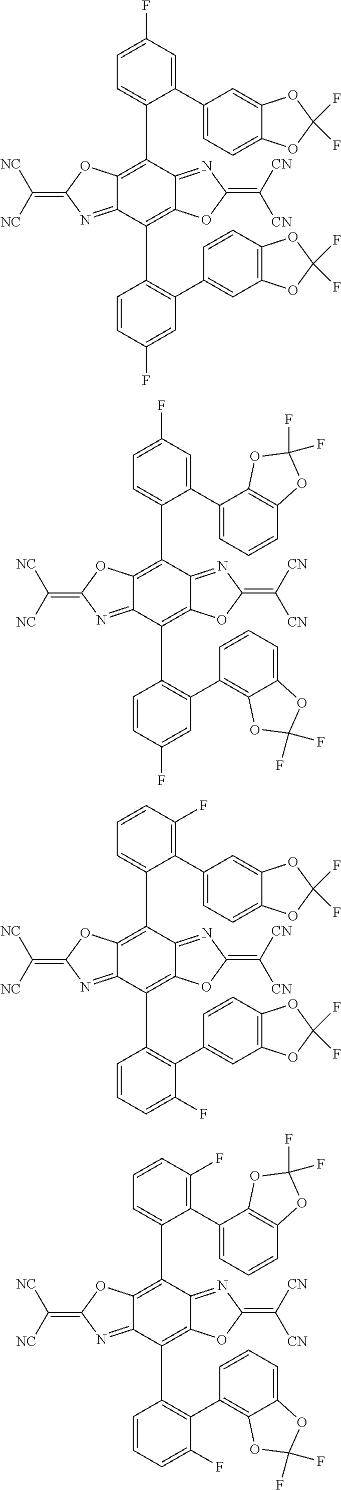

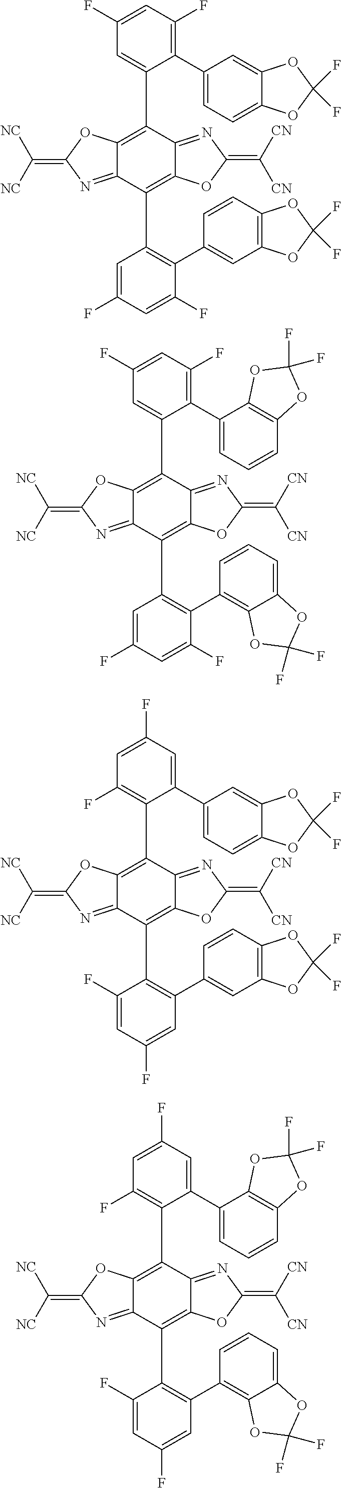

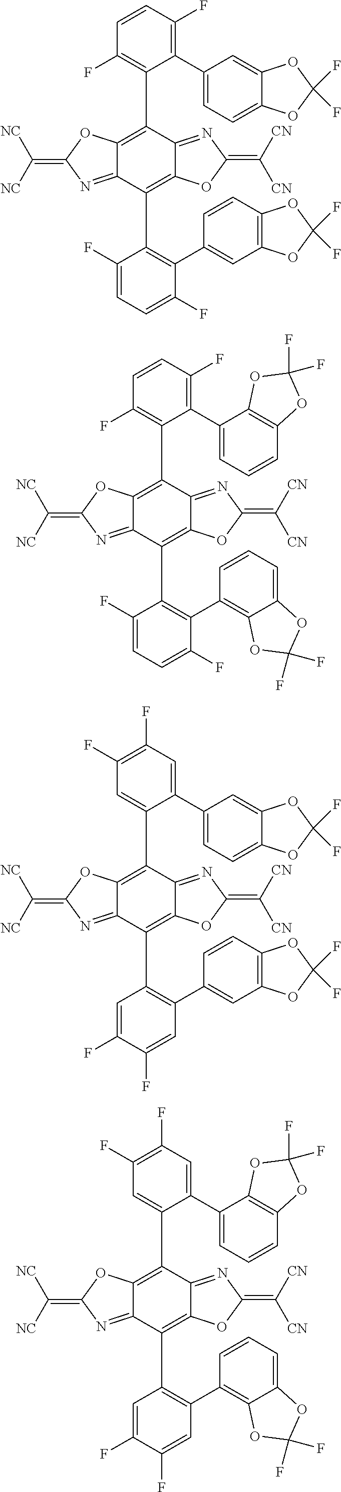

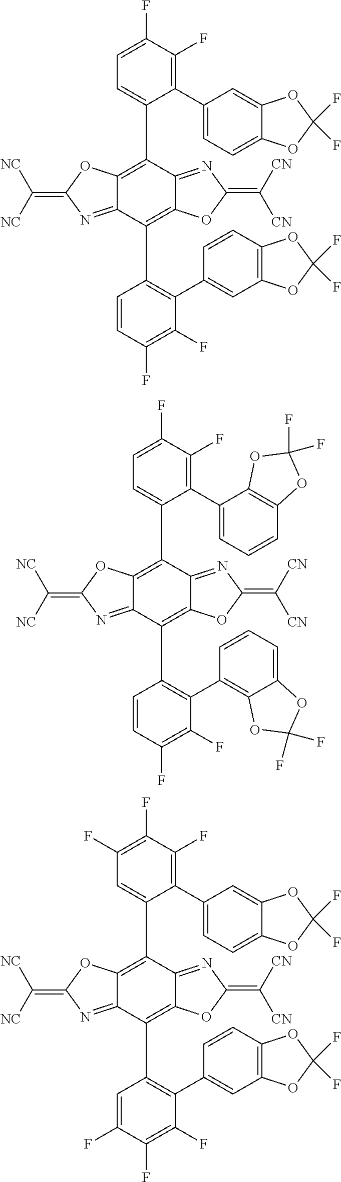

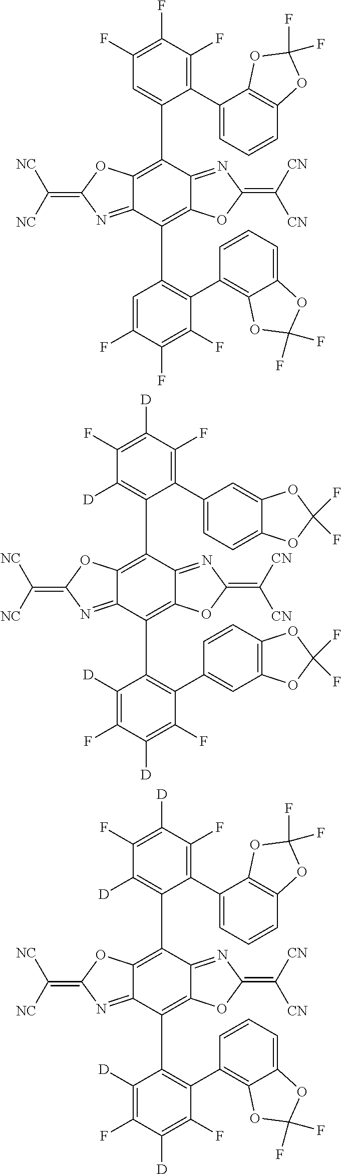

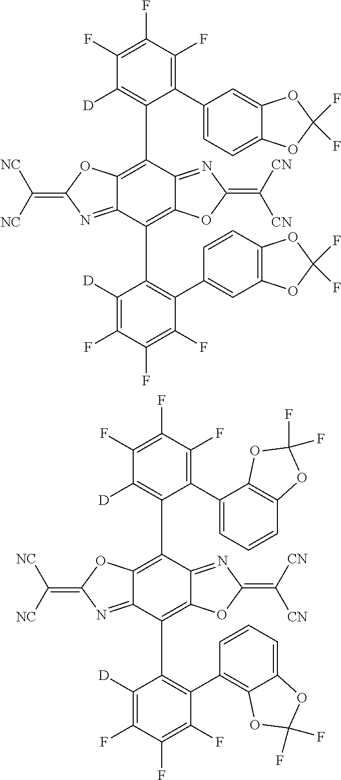

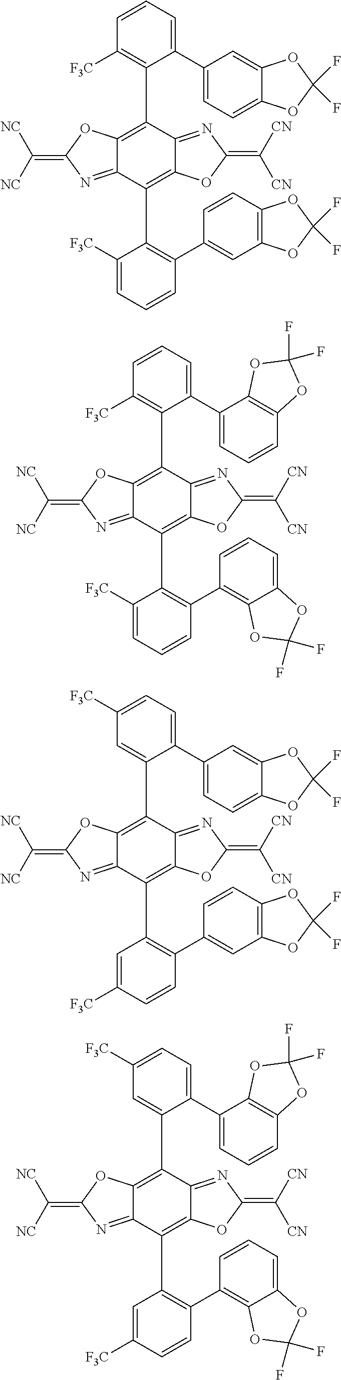

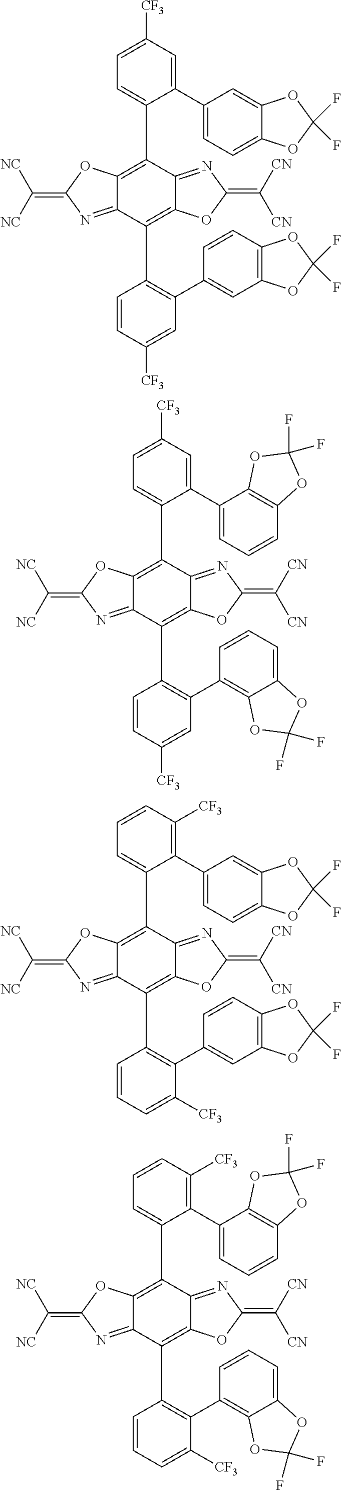

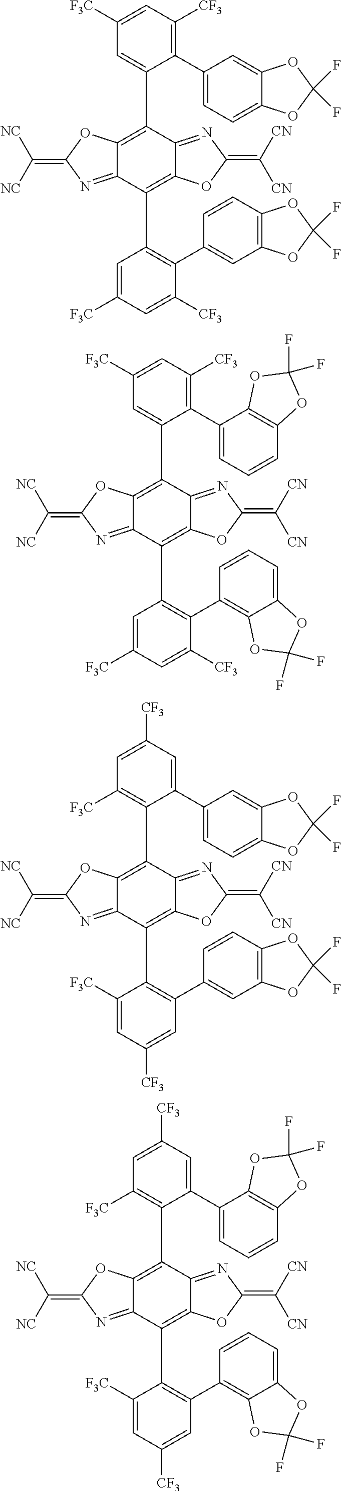

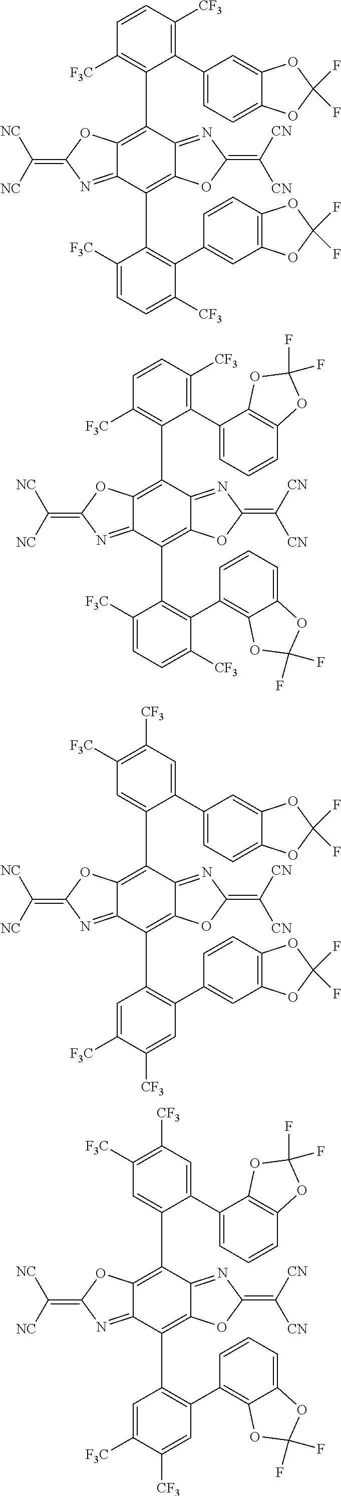

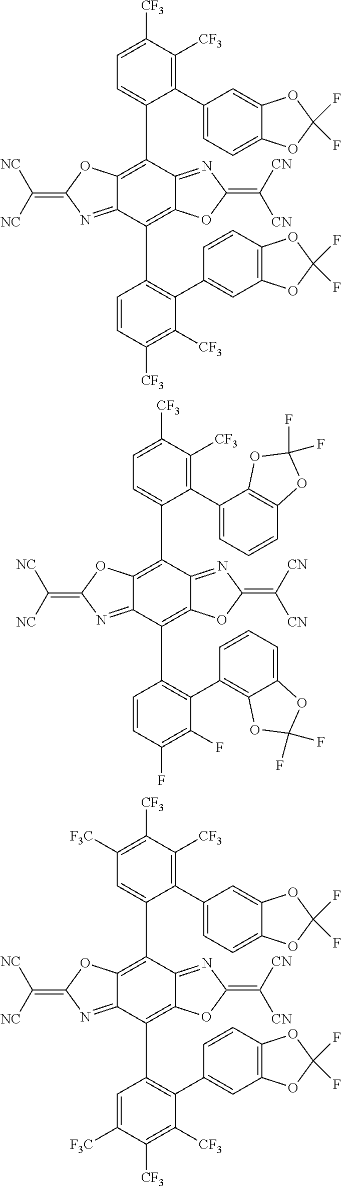

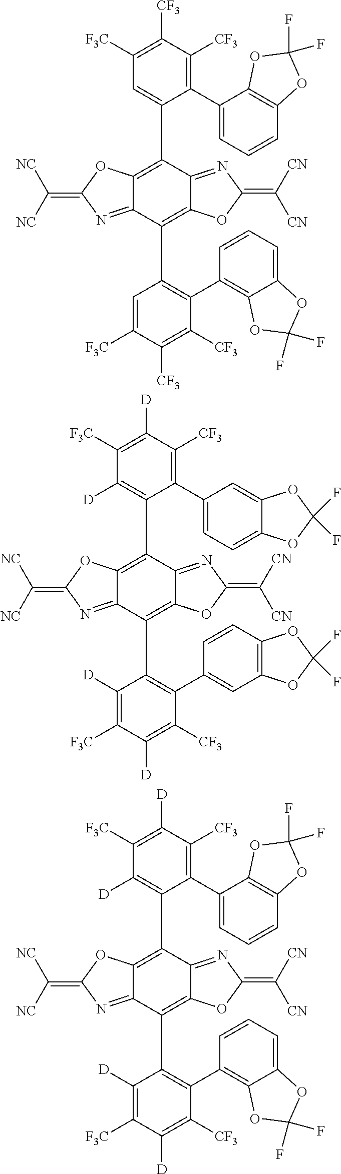

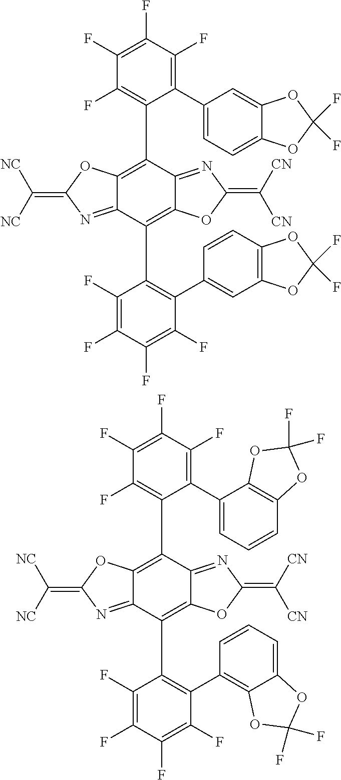

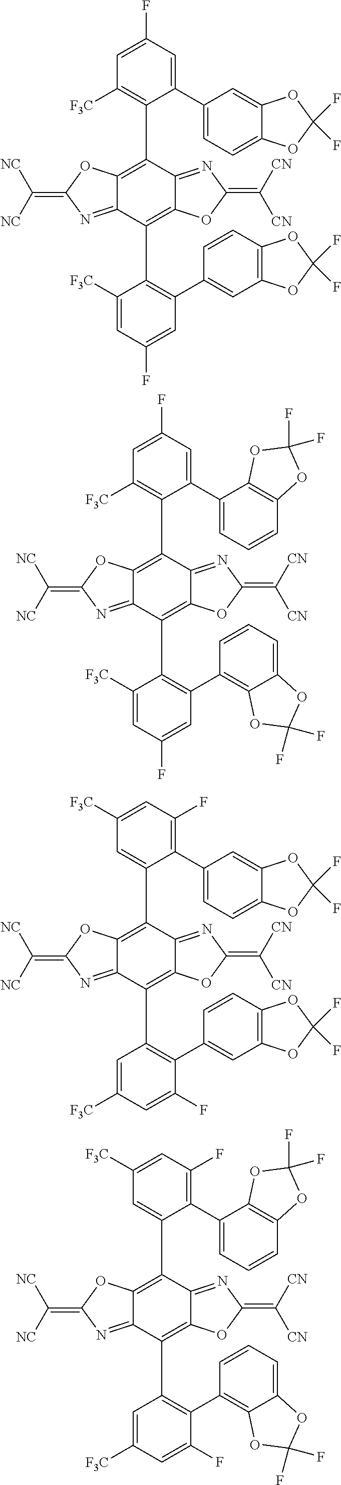

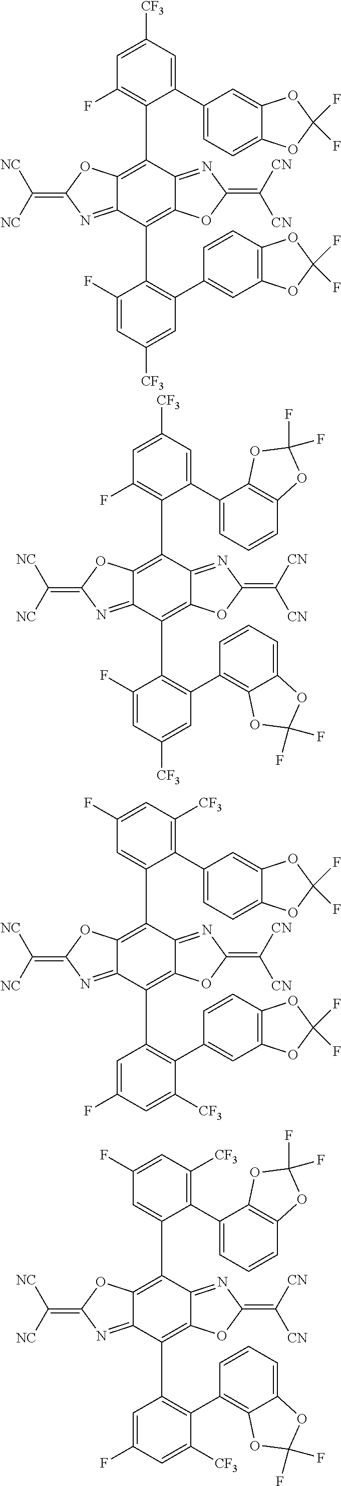

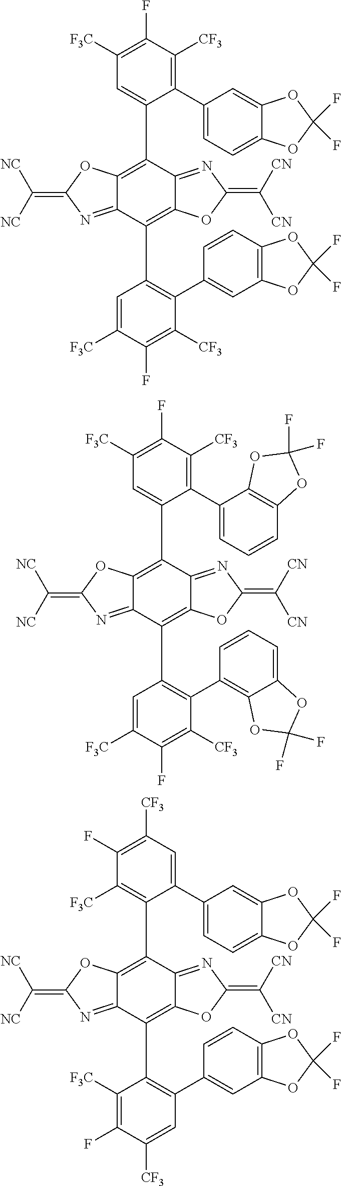

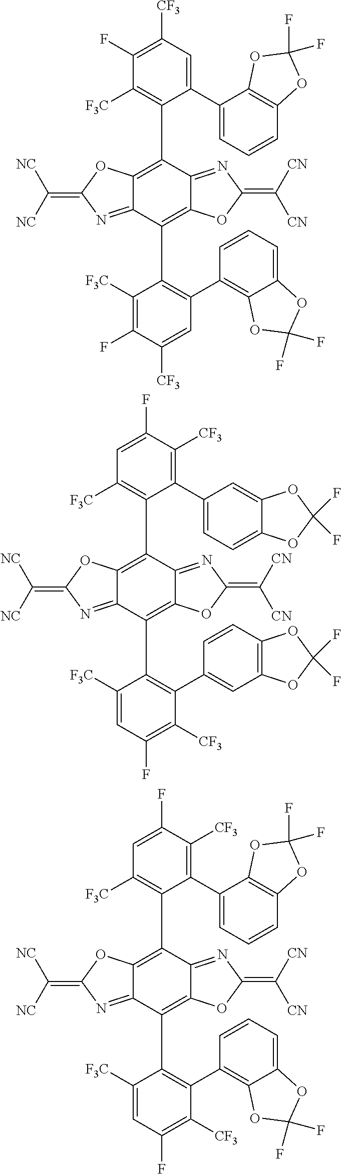

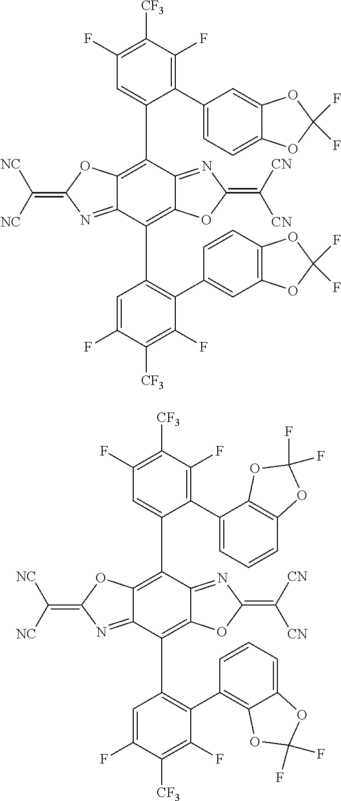

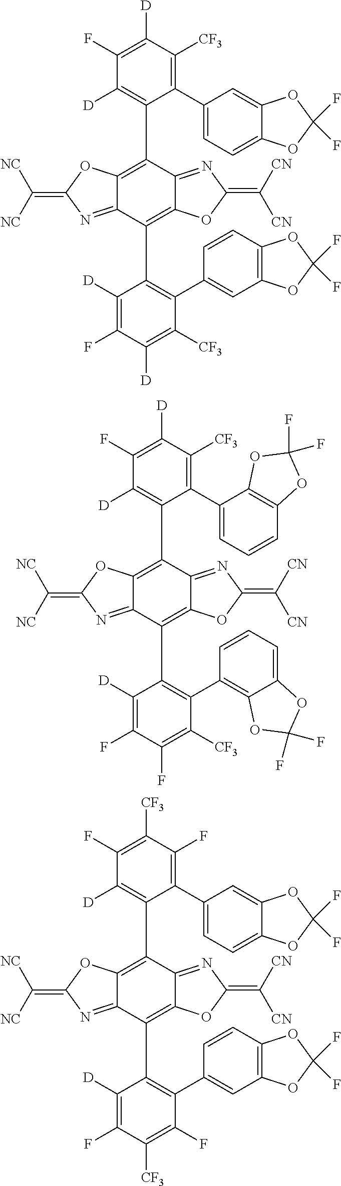

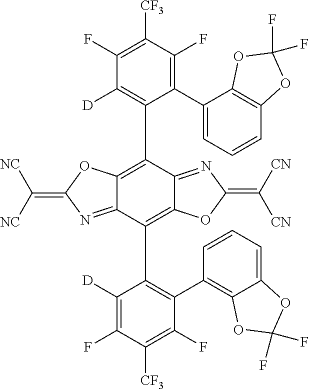 [SMILES: [2H]c1c(F)c(C(F)(F)F)c(F)c(-c2cccc3c2OC(F)(F)O3)c1-c1c2nc(=C(C#N)C#N)oc2c(-c2c([2H])c(F)c(C(F)(F)F)c(F)c2-c2cccc3c2OC(F)(F)O3)c2nc(=C(C#N)C#N)oc12]

hydrogens in each of the above compounds can be partially or completely replaced by deuterium.

A second aspect of the present invention provides an organic electroluminescent device, comprising:
an anode,
a cathode,
and an organic layer arranged between the anode and the cathode, wherein the organic layer comprises the compound as described above.

Furthermore, the organic layer is a hole injection layer or a hole transport layer, and the hole injection layer or the hole transport layer is formed from the compound as described above alone.

Furthermore, the organic layer is a hole injection layer or a hole transport layer, and the hole injection layer or the hole transport layer comprises the compound for an organic electroluminescent device, as described above, and at least one hole transport material, the mass doping ratio of the organic compound to the at least one hole transport material being 1000:1 to 1:1000, preferably 10:1 to 1:100.

Furthermore, the organic electroluminescent device comprises at least two light-emitting units, and the organic layer is a charge generation layer arranged between the at least two light-emitting units, wherein the charge generation layer comprises a p-type charge generation layer and an n-type charge generation layer;

the p-type charge generation layer comprises the organic compound as described above and at least one hole transport material, the mass doping ratio of the organic compound to the at least one hole transport material being 1000:1 to 1:1000, preferably 10:1 to 1:100.

Furthermore, the hole transport material is selected from compounds having triarylamine units, spirobifluorene compounds, pentacene compounds, oligothiophene compounds, oligophenyl compounds, oligo (phenylene vinylene) compounds, oligofluorene compounds, porphyrin complexes, and metal phthalocyanine complexes.

Furthermore, the charge generation layer further comprises a buffer layer arranged between the p-type charge generation layer and the n-type charge generation layer, and the buffer layer comprises the compound as described above.

A third aspect of the present invention provides a display assembly, comprising the organic electroluminescent device as described above.

### Beneficial Effects of the Invention

The present invention provides a compound for an organic electroluminescent device and an organic electroluminescent device comprising the compound. The compound provided by the present invention is a dehydrogenated fused-ring compound with a plurality of substituent groups, wherein the substituent groups contain a fluorobenzodioxole structure, and the unique fluorobenzodioxole structure has not only good thermal stability but also stable electron-withdrawing ability; and by connecting the unique fluorobenzodioxole structure to the multi-substituted dehydrogenated fused-ring parent nucleus, not only can the thermal stability of the material be improved, but also the material exhibits superior doping ability; and when the compound provided by the present invention is used for preparing an organic electroluminescent device, not only can the hole injection ability of the hole injection layer be improved, resulting the voltage of the device being reduced, but also the efficiency and lifetime of the device can be improved.

### BRIEF DESCRIPTION OF THE DRAWINGS

FIG. 1 is a schematic diagram of an organic electroluminescent device according to an embodiment in the description of the present invention, in which a device 100 comprises a substrate 101, an anode 110, a hole injection layer 120, a hole transport layer 130, an electron barrier layer 140, a light-emitting layer 150, a hole barrier layer 160, an electron transport layer 170, an electron injection layer 180, and a cathode 190.

FIG. 2 is a schematic diagram of an organic light-emitting device with an encapsulation layer according to an embodiment in the description of the present invention, in which a device 200 comprises a substrate 201, an anode 210, a hole injection layer 220, a hole transport layer 230, an electron barrier layer 240, a light-emitting layer 250, a hole barrier layer 260, an electron transport layer 270, an electron injection layer 280, a cathode 290, and an encapsulation layer 202.

FIG. 3 is a schematic diagram of a tandem organic light-emitting device with an encapsulation layer according to an embodiment of the description of the present invention, in which a device 300 comprises a substrate 301, an anode 310, a first hole injection layer 311, a first hole transport layer 312, a first electron barrier layer 313, a first light-emitting layer 314, a first hole barrier layer 315, a first electron transport layer 316, an n-type charge generation layer 320, a p-type charge generation layer 321, a second hole injection layer 330, a second hole transport layer 331, a second electron barrier layer 332, a second light-emitting layer 333, a second hole barrier layer 334, a second electron transport layer 335, a second electron injection layer 336, a cathode 337, and an encapsulation layer 302.

### DETAILED DESCRIPTION OF EMBODIMENTS

In order to explain the present invention more clearly, the present invention will be further explained below in conjunction with preferred examples and the accompanying drawings. A person skilled in the art should understand that the following detailed description is illustrative rather than restrictive, and should not limit the scope of protection of the present invention. The examples and comparative examples in the present description are provided to explain the present description more completely to those skilled in the art. The examples and comparative examples according to the present description can be transformed into various forms, and the scope of protection of the present invention should not be limited to the examples and comparative examples detailed below.

The organic compound of the present invention is suitable for light-emitting elements, display panels, and electronic devices, especially for organic electroluminescent devices. The electronic device of the present invention is a device comprising a layer of at least one organic compound, and the device may also comprise an inorganic material or a layer formed entirely of an inorganic material. The electronic device is preferably an organic electroluminescent device, an organic integrated circuit, an organic field effect transistor, an organic thin film transistor, an organic light-emitting transistor, an organic solar cell, an organic dye-sensitized solar cell, an organic optical detector, an organic photosensor, an organic field-quenching device, a luminescent electrochemical cell, an organic laser diode, and an organic plasma emitting device. The electronic device is preferably an organic electroluminescent device.

The preparation method for the organic electroluminescent device is not limited, and the preparation method of the following examples is only an example and should not be understood as a limitation. Those skilled in the art can rationally modify the preparation method of the following examples according to the prior art. By way of example, the ratio of various materials in each organic layer is not particularly limited, and those skilled in the art can make a rational selection in a certain range according to the prior art. In the device examples, the characteristics of the devices are also tested by using conventional equipment in the art and methods well known to those skilled in the art. Since those skilled in the art are all aware of related contents such as the use of the above equipment and test methods and can definitely obtain the inherent data of the sample without interference, the above related contents are no more repeated in the present patent.

### SYNTHESIS EXAMPLES

The preparation method for the compound of the present invention is not limited, and the raw materials used can be either purchased or synthesized in-house.

The preparation method for the compound of the present invention is not limited. Typically, but not by way of limitation, the following compound is provided as an example, and the synthesis route and preparation method thereof are as follows.

### Synthesis Example 1: Synthesis of Compound PD1

### Step 1: Synthesis of Intermediate PD1-A

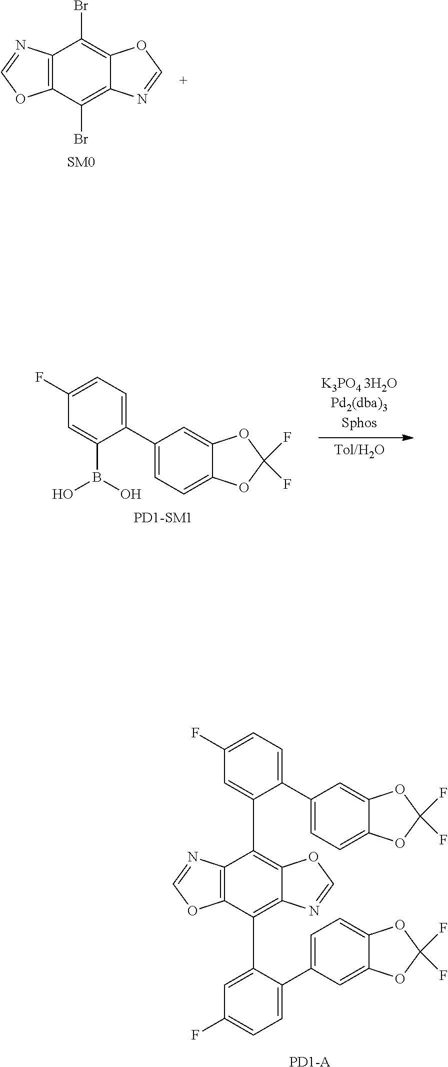

In a 2 L two-necked flask, intermediate SM0 (10.6 g, 33.3 mmol), intermediate PD1-SM1 (34.5 g, 116.5 mmol), potassium phosphate trihydrate (36.2 g, 136.2 mmol), Pd₂(dba)₃ (1.46 g, 1.59 mmol), and 2-dicyclohexylphosphino-2′,6′-dimethoxybiphenyl (SPhos, 2.26 g, 5.50 mmol) were successively added. After nitrogen displacement three times, 800 mL of toluene and 200 mL of water were added under nitrogen protection, and the mixture was heated to 100° C. and reacted overnight. After the reaction was complete, the reaction liquid was cooled and extracted by adding an appropriate amount of tetrahydrofuran, and the extract liquor was dried over anhydrous magnesium sulfate, concentrated and then purified by column chromatography to obtain intermediate PD1-A as a white solid (18.0 g, yield 82%).

### Step 2: Synthesis of Intermediate PD1-B

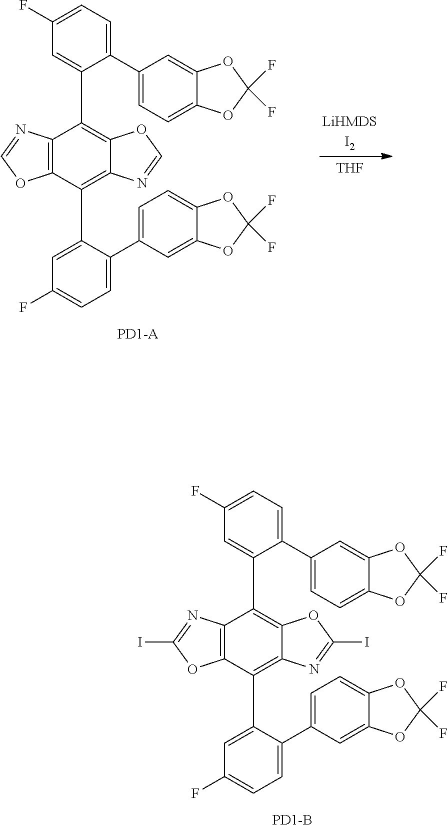

In a 2 L two-necked flask, intermediate PD1-A (18.0 g, 27.3 mmol) was added, 800 mL of ultradry THF was added under nitrogen protection, and the mixture was cooled to −30° C. Lithium bis(trimethylsilyl)amide (LiHMDS, 65 mL, 65 mmol) was then dropwise added. The mixture was reacted at this temperature for 2 h. Elemental iodine (17.8 g, 70.2 mmol) was then added, and the mixture was heated to room temperature and reacted for 0.5 h. The reaction liquid was quenched with a saturated sodium sulfite solution and extracted by adding an appropriate amount of ethyl acetate, and the extract liquor was dried over anhydrous magnesium sulfate, concentrated and then purified by column chromatography to obtain intermediate PD1-B as a white solid (22.4 g, yield 90%).

### Step 3: Synthesis of Intermediate PD1-C

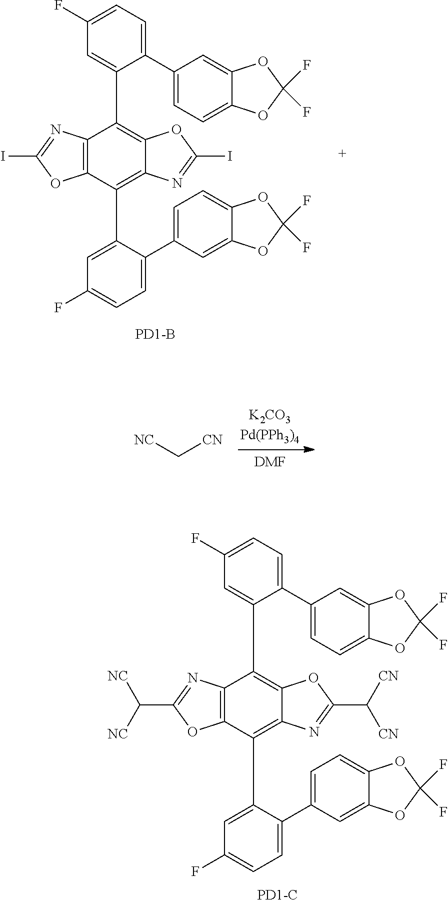

In a 2 L two-necked flask, intermediate PD1-B (22.4 g, 24.6 mmol), malononitrile (6.31 g, 95.6 mmol), potassium carbonate (13.6 g, 98.4 mmol), and Pd(PPh₃)₄ (0.340 g, 0.294 mmol) were successively added, 350 mL of DMF was added under nitrogen protection, and the mixture was heated to 80° C. and reacted overnight. After the reaction was complete, the reaction liquid was cooled to room temperature and cooled in an ice-water bath. The reaction liquid was slowly dropwise added to 3N hydrochloric acid to precipitate a large amount of a yellow solid, which was filtered to obtain a crude product. After crystallization, intermediate PD1-C as a white solid (15.7 g, yield 81%) was obtained.

### Step 4: Synthesis of Compound PD1

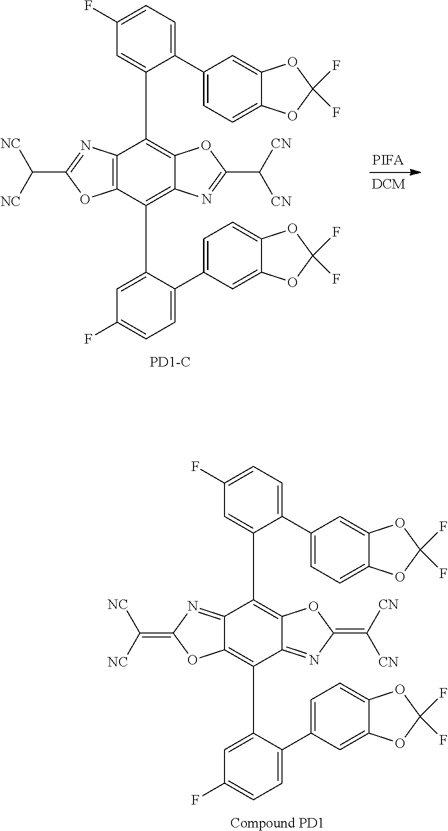

In a nitrogen atmosphere, to a 3 L single-necked flask, intermediate PD1-C (15.7 g, 19.9 mmol) and then 1000 mL of DCM were added, and bis(trifluoroacetoxy) iodobenzene (PIFA, 16.7 g, 38.8 mmol) was added in portions at room temperature. After stirring at room temperature for 2 days, the reaction liquid was concentrated to an appropriate volume and filtered to obtain compound PD1 as a black solid (13.0 g, yield 83%). The product was confirmed to be the target compound with a molecular weight of 786.0.

### Synthesis Example 2: Synthesis of Compound PD2

### Step 1: Synthesis of Intermediate PD2-A

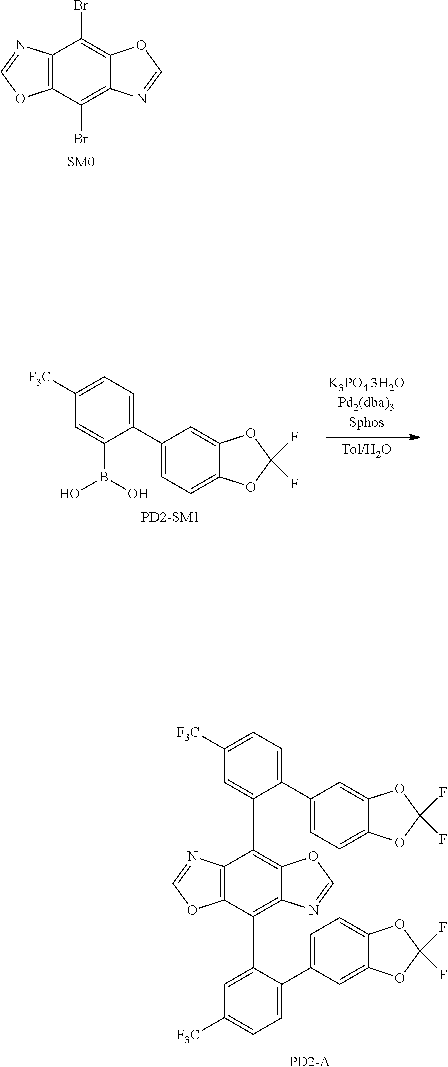

In a 2 L two-necked flask, intermediate SM0 (11.5 g, 36.2 mmol), intermediate PD2-SM1 (41.7 g, 120.5 mmol), potassium phosphate trihydrate (36.2 g, 136.2 mmol), Pd₂(dba)₃ (1.68 g, 1.832 mmol), and 2-dicyclohexylphosphino-2′,6′-dimethoxybiphenyl (SPhos, 2.25 g, 5.48 mmol) were successively added. After nitrogen displacement three times, 800 mL of toluene and 200 ml of water were added under nitrogen protection, and the mixture was heated to 100° C. and reacted overnight. After the reaction was complete, the reaction liquid was cooled and extracted by adding an appropriate amount of tetrahydrofuran, and the extract liquor was dried over anhydrous magnesium sulfate, concentrated and then purified by column chromatography to obtain intermediate PD2-A as a white solid (19.5 g, yield 71%).

### Step 2: Synthesis of Intermediate PD2-B

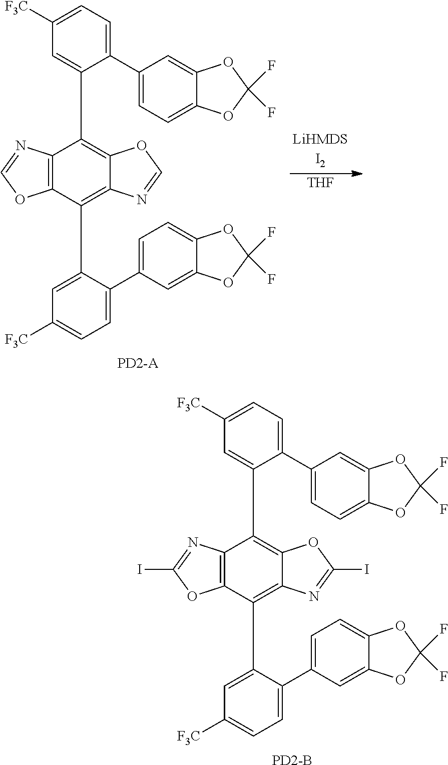

In a 2 L two-necked flask, intermediate PD2-A (19.5 g, 25.7 mmol) was added, 800 mL of ultradry THF was added under nitrogen protection, and the mixture was cooled to −30° C. Lithium bis(trimethylsilyl)amide (LiHMDS, 60 mL, 60 mmol) was then dropwise added. The mixture was reacted at this temperature for 2 h. Elemental iodine (18.4 g, 72.3 mmol) was then added, and the mixture was heated to room temperature and reacted for 0.5 h. The reaction liquid was quenched with a saturated sodium sulfite solution and extracted by adding an appropriate amount of ethyl acetate, and the extract liquor was dried over anhydrous magnesium sulfate, concentrated and then purified by column chromatography to obtain intermediate PD2-B as a white solid (22.4 g, yield 86%).

### Step 3: Synthesis of Intermediate PD2-C

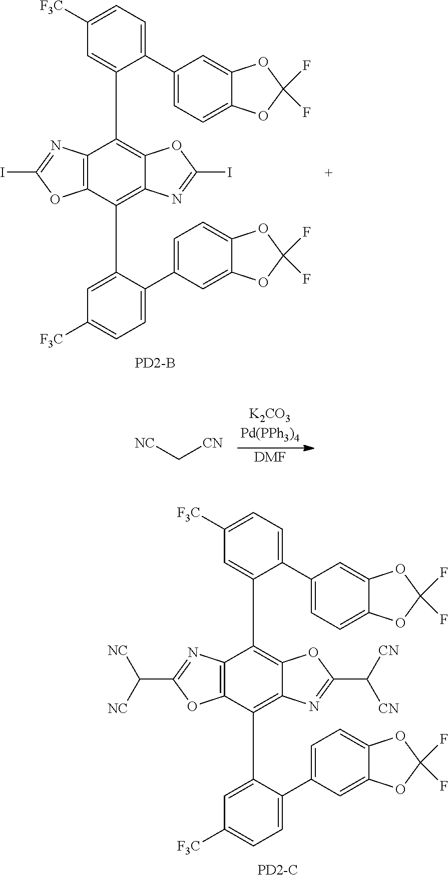

In a 2 L two-necked flask, intermediate PD2-B (22.4 g, 22.1 mmol), malononitrile (5.85 g, 88.6 mmol), potassium carbonate (12.8 g, 92.4 mmol), and Pd(PPh₃)₄ (0.326 g, 0.282 mmol) were successively added, 350 mL of DMF was added under nitrogen protection, and the mixture was heated to 80° C. and reacted overnight. After the reaction was complete, the reaction liquid was cooled to room temperature and cooled in an ice-water bath. The reaction liquid was slowly dropwise added to 3N hydrochloric acid to precipitate a large amount of a yellow solid, which was filtered to obtain a crude product. After crystallization, intermediate PD2-C as a white solid (16.1 g, yield 82%) was obtained.

### Step 4: Synthesis of Compound PD2

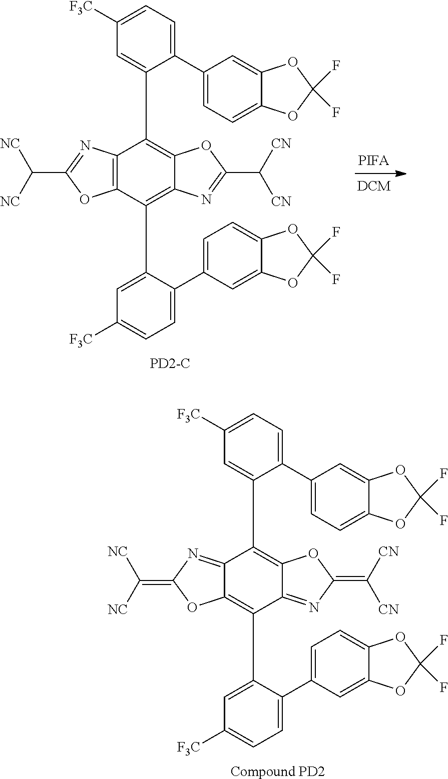

In a nitrogen atmosphere, to a 3 L single-necked flask, intermediate PD2-C (16.1 18.1 mmol) and then 1000 mL of DCM were added, and g, bis(trifluoroacetoxy) iodobenzene (PIFA, 15.8 g, 36.8 mmol) is added in portions at room temperature. After stirring at room temperature for 2 days, the reaction liquid was concentrated to an appropriate volume and filtered to obtain compound PD2 as a black solid (12.0 g, yield 75%). The product was confirmed to be the target compound with a molecular weight of 886.0.

### Synthesis Example 3: Synthesis of Compound PD3

### Step 1: Synthesis of Intermediate PD3-A

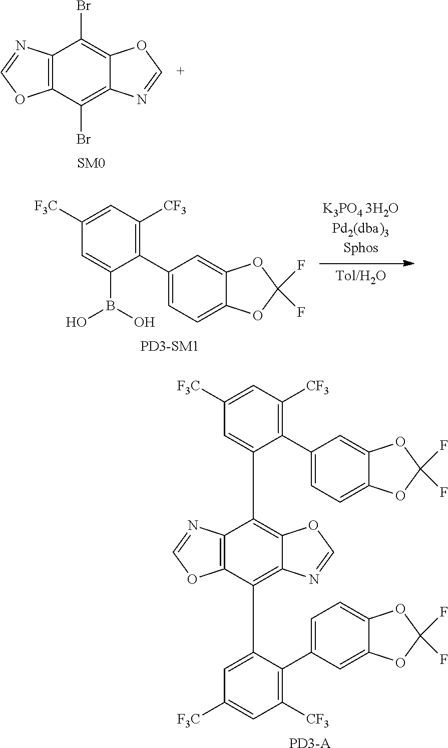

In a 2 L two-necked flask, intermediate SM0 (10.2 g, 32.2 mmol), intermediate PD3-SM1 (38.0 g, 91.8 mmol), potassium phosphate trihydrate (28.0 g, 105.2 mmol), Pd₂(dba)₃ (1.52 g, 1.654 mmol), and 2-dicyclohexylphosphino-2′,6′-dimethoxybiphenyl (SPhos, 2.13 g, 5.19 mmol) were successively added. After nitrogen displacement three times, 800 mL of toluene and 200 ml of water were added under nitrogen protection, and the mixture was heated to 100° C. and reacted overnight. After the reaction was complete, the reaction liquid was cooled and extracted by adding an appropriate amount of tetrahydrofuran, and the extract liquor was dried over anhydrous magnesium sulfate, concentrated and then purified by column chromatography to obtain intermediate PD3-A as a white solid (18.8 g, yield 65%).

### Step 2: Synthesis of Intermediate PD3-B

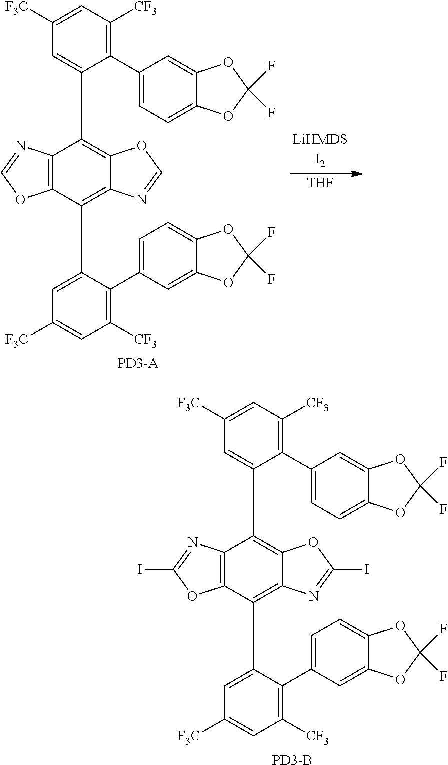

In a 2 L two-necked flask, intermediate PD3-A (18.8 g, 20.9 mmol) was added, 800 mL of ultradry THF was added under nitrogen protection, and the mixture was cooled to −30° C. Lithium bis(trimethylsilyl)amide (LiHMDS, 60 mL, 60 mmol) was then dropwise added. The mixture was reacted at this temperature for 2 h. Elemental iodine (16.6 g, 65.3 mmol) was then added, and the mixture was heated to room temperature and reacted for 0.5 h. The reaction liquid was quenched with a saturated sodium sulfite solution and extracted by adding an appropriate amount of ethyl acetate, and the extract liquor was dried over anhydrous magnesium sulfate, concentrated and then purified by column chromatography to obtain intermediate PD3-B as a white solid (21.1 g, yield 88%).

### Step 3: Synthesis of Intermediate PD3-C

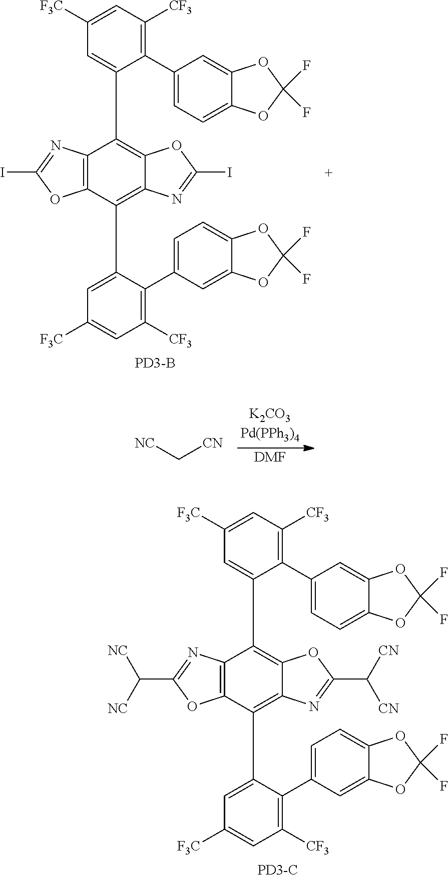

In a 2 L two-necked flask, intermediate PD3-B (21.1 g, 18.4 mmol), malononitrile (5.00 g, 75.8 mmol), potassium carbonate (11.2 g, 81.2 mmol), and Pd(PPh₃)₄ (0.229 g, 0.198 mmol) were successively added, 350 mL of DMF was added under nitrogen protection, and the mixture was heated to 80° C. and reacted overnight. After the reaction was complete, the reaction liquid was cooled to room temperature and cooled in an ice-water bath. The reaction liquid was slowly dropwise added to 3N hydrochloric acid to precipitate a large amount of a yellow solid, which was filtered to obtain a crude product. After crystallization, intermediate PD3-C as a white solid (13.6 g, yield 72%) was obtained.

### Step 4: Synthesis of Compound PD3

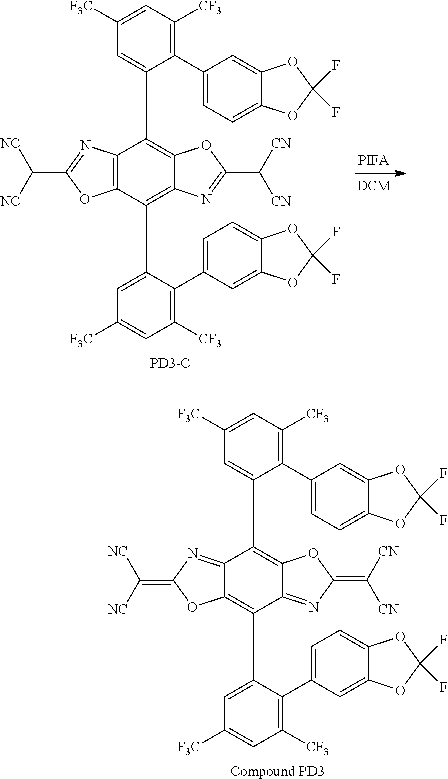

In a nitrogen atmosphere, to a 3 L single-necked flask, intermediate PD3-C (13.6 g, 13.2 mmol) and then 1000 mL of DCM were added, and bis(trifluoroacetoxy) iodobenzene (PIFA, 11.0 g, 25.6 mmol) was added in portions at room temperature. After stirring at room temperature for 2 days, the reaction liquid was concentrated to an appropriate volume and filtered to obtain compound PD3 as a black solid (10.3 g, yield 78%). The product was confirmed to be the target compound with a molecular weight of 1022.0.

### Synthesis Example 4: Synthesis of Compound PD4

### Step 1: Synthesis of Intermediate PD4-A

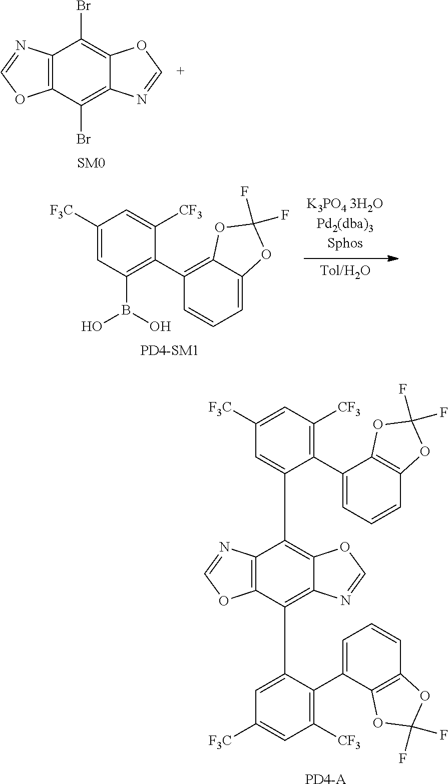

In a 2 L two-necked flask, intermediate SM0 (10.6 g, 33.4 mmol), intermediate PD4-SM1 (40.8 g, 98.5 mmol), potassium phosphate trihydrate (29.2 g, 109.8 mmol), Pd₂(dba)₃ (1.76 g, 1.924 mmol), and 2-dicyclohexylphosphino-2′,6′-dimethoxybiphenyl (SPhos, 3.38 g, 8.24 mmol) were successively added. After nitrogen displacement three times, 800 mL of toluene and 200 ml of water were added under nitrogen protection, and the mixture was heated to 100° C. and reacted overnight. After the reaction was complete, the reaction liquid was cooled and extracted by adding an appropriate amount of tetrahydrofuran, and the extract liquor was dried over anhydrous magnesium sulfate, concentrated and then purified by column chromatography to obtain intermediate PD4-A as a white solid (19.5 g, yield 65%).

### Step 2: Synthesis of Intermediate PD4-B

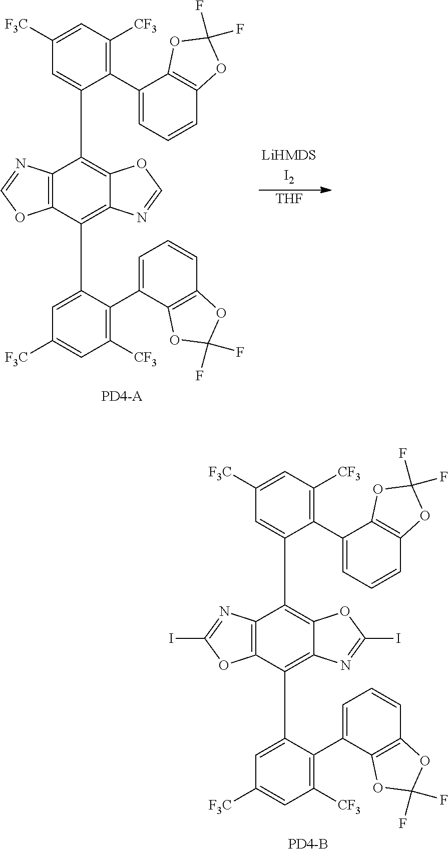

In a 2 L two-necked flask, intermediate PD4-A (19.5 g, 21.7 mmol) was added, 800 mL of ultradry THF was added under nitrogen protection, and the mixture was cooled to −30° C. Lithium bis(trimethylsilyl)amide (LiHMDS, 60 mL, 60 mmol) was then dropwise added. The mixture was reacted at this temperature for 2 h. Elemental iodine (16.8 g, 66.2 mmol) was then added, and the mixture was heated to room temperature and reacted for 0.5 h. The reaction liquid was quenched with a saturated sodium sulfite solution and extracted by adding an appropriate amount of ethyl acetate, and the extract liquor was dried over anhydrous magnesium sulfate, concentrated and then purified by column chromatography to obtain intermediate PD4-B as a white solid (21.4 g, yield 86%).

### Step 3: Synthesis of Intermediate PD4-C

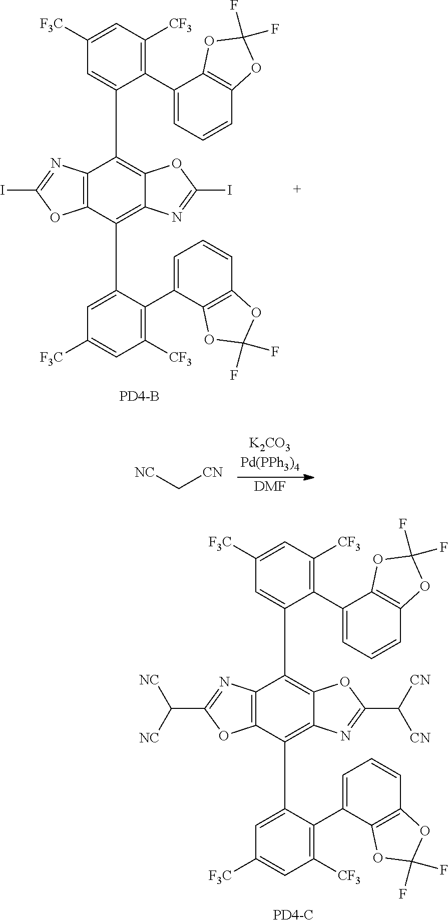

In a 2 L two-necked flask, intermediate PD4-B (21.4 g, 18.7 mmol), malononitrile (5.17 g, 78.4 mmol), potassium carbonate (12.3 g, 88.8 mmol), and Pd(PPh₃)₄ (0.310 g, 0.268 mmol) were successively added, 350 mL of DMF was added under nitrogen protection, and the mixture was heated to 80° C. and reacted overnight. After the reaction was complete, the reaction liquid was cooled to room temperature and cooled in an ice-water bath. The reaction liquid was slowly dropwise added to 3N hydrochloric acid to precipitate a large amount of a yellow solid, which was filtered to obtain a crude product. After crystallization, intermediate PD4-C as a white solid (13.8 g, yield 72%) was obtained.

### Step 4: Synthesis of Compound PD4

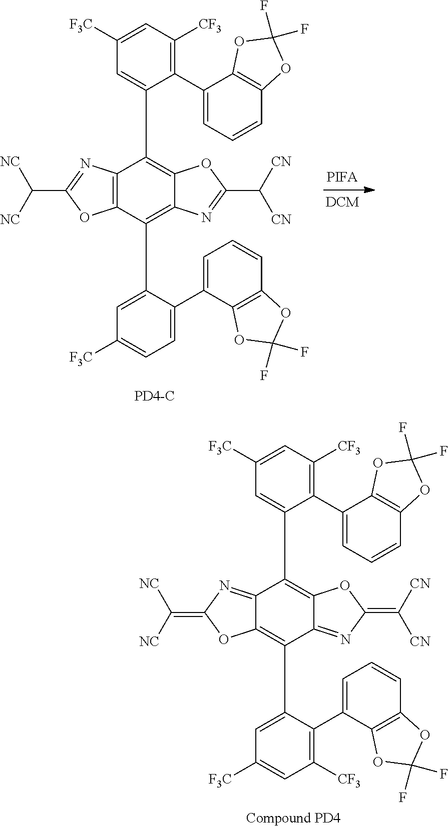

In a nitrogen atmosphere, to a 3 L single-necked flask, intermediate PD4-C (13.8 g, 13.5 mmol) and then 1000 mL of DCM were added, and bis(trifluoroacetoxy) iodobenzene (PIFA, 11.0 g, 25.6 mmol) was added in portions at room temperature. After stirring at room temperature for 2 days, the reaction liquid was concentrated to an appropriate volume and filtered to obtain compound PD4 as a black solid (10.5 g, yield 76%). The product was confirmed to be the target compound with a molecular weight of 1022.0.

### Synthesis Example 5: Synthesis of Compound PD5

### Step 1: Synthesis of Intermediate PD5-A

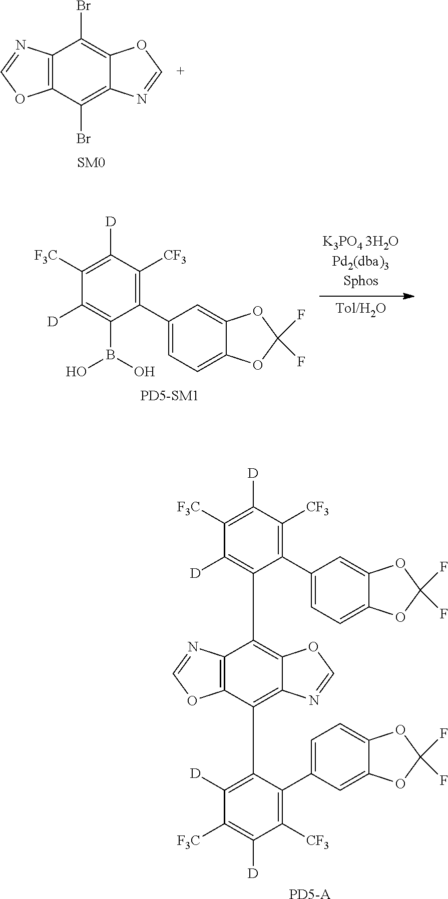

In a 2 L two-necked flask, intermediate SM0 (11.7 g, 36.8 mmol), intermediate PD5-SM1 (42.1 g, 101.2 mmol), potassium phosphate trihydrate (28.8 g, 108.3 mmol), Pd₂(dba)₃ (1.82 g, 1.987 mmol), and 2-dicyclohexylphosphino-2′,6′-dimethoxybiphenyl (SPhos, 2.26 g, 5.51 mmol) were successively added. After nitrogen displacement three times, 800 mL of toluene and 200 ml of water were added under nitrogen protection, and the mixture was heated to 100° C. and reacted overnight. After the reaction was complete, the reaction liquid was cooled and extracted by adding an appropriate amount of tetrahydrofuran, and the extract liquor was dried over anhydrous magnesium sulfate, concentrated and then purified by column chromatography to obtain intermediate PD5-A as a white solid (22.2 g, yield 67%).

### Step 2: Synthesis of Intermediate PD5-B

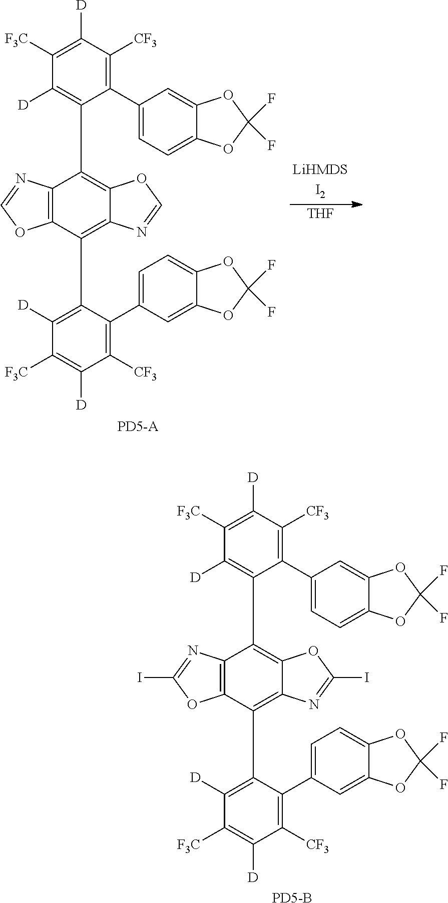

In a 2 L two-necked flask, intermediate PD5-A (22.2 g, 24.7 mmol) was added, 800 mL of ultradry THF was added under nitrogen protection, and the mixture was cooled to −30° C. Lithium bis(trimethylsilyl)amide (LiHMDS, 60 mL, 60 mmol) was then dropwise added. The mixture was reacted at this temperature for 2 h. Elemental iodine (17.8 g, 70.1 mmol) was then added, and the mixture was heated to room temperature and reacted for 0.5 h. The reaction liquid was quenched with a saturated sodium sulfite solution and extracted by adding an appropriate amount of ethyl acetate, and the extract liquor was dried over anhydrous magnesium sulfate, concentrated and then purified by column chromatography to obtain intermediate PD5-B as a white solid (25.3 g, yield 89%).

### Step 3: Synthesis of Intermediate PD5-C

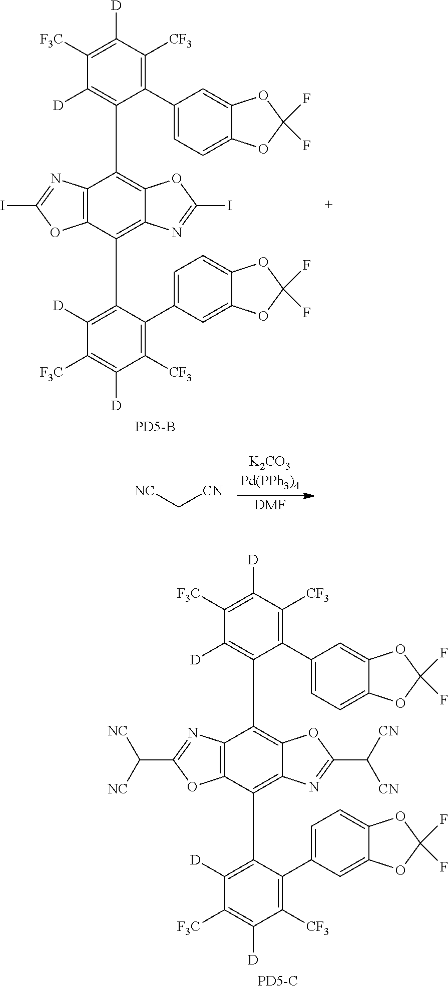

In a 2 L two-necked flask, intermediate PD5-B (25.3 g, 21.9 mmol), malononitrile (5.23 g, 79.2 mmol), potassium carbonate (11.1 g, 80.3 mmol), and Pd(PPh₃)₄ (0.209 g, 0.181 mmol) were successively added, 350 mL of DMF was added under nitrogen protection, and the mixture was heated to 80° C. and reacted overnight. After the reaction was complete, the reaction liquid was cooled to room temperature and cooled in an ice-water bath. The reaction liquid was slowly dropwise added to 3N hydrochloric acid to precipitate a large amount of a yellow solid, which was filtered to obtain a crude product. After crystallization, intermediate PD5-C as a white solid (17.6 g, yield 78%) was obtained.

### Step 4: Synthesis of Compound PD5

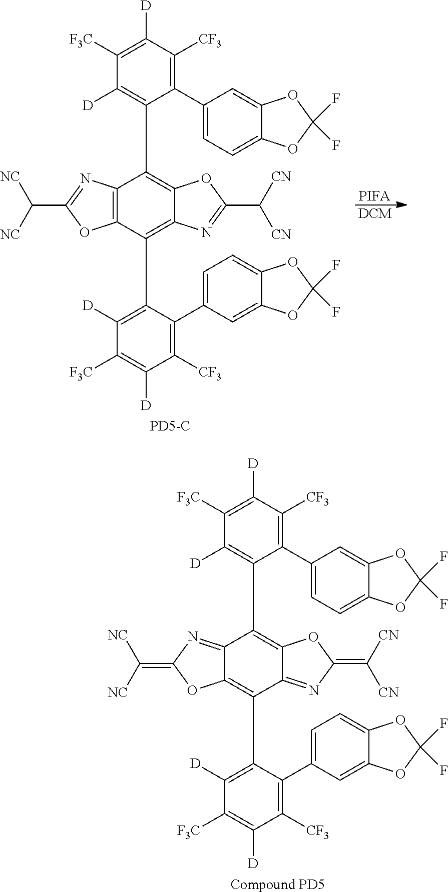

In a nitrogen atmosphere, to a 3 L single-necked flask, intermediate PD5-C (17.6 g, 17.1 mmol) and then 1000 mL of DCM were added, and bis(trifluoroacetoxy) iodobenzene (PIFA, 11.0 g, 25.6 mmol) was added in portions at room temperature. After stirring at room temperature for 2 days, the reaction liquid was concentrated to an appropriate volume and filtered to obtain compound PD5 as a black solid (14.2 g, yield 81%). The product was confirmed to be the target compound with a molecular weight of 1026.0.

### Comparative Compounds

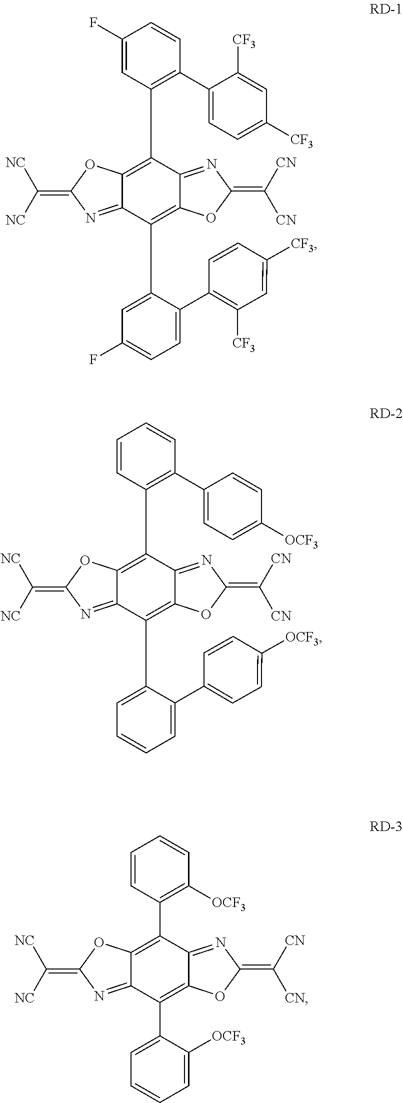 [SMILES: N#CC(C#N)=c1nc2c(-c3cc(F)ccc3-c3ccc(C(F)(F)F)cc3C(F)(F)F)c3oc(=C(C#N)C#N)nc3c(-c3cc(F)ccc3-c3ccc(C(F)(F)F)cc3C(F)(F)F)c2o1 ; N#CC(C#N)=c1nc2c(-c3ccccc3-c3ccc(OC(F)(F)F)cc3)c3oc(=C(C#N)C#N)nc3c(-c3ccccc3-c3ccc(OC(F)(F)F)cc3)c2o1 ; N#CC(C#N)=c1nc2c(-c3ccccc3OC(F)(F)F)c3oc(=C(C#N)C#N)nc3c(-c3ccccc3OC(F)(F)F)c2o1]

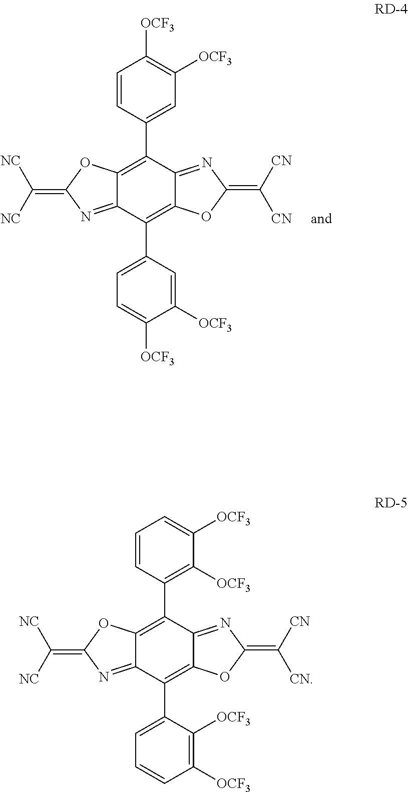 [SMILES: N#CC(C#N)=c1nc2c(-c3ccc(OC(F)(F)F)c(OC(F)(F)F)c3)c3oc(=C(C#N)C#N)nc3c(-c3ccc(OC(F)(F)F)c(OC(F)(F)F)c3)c2o1 ; N#CC(C#N)=c1nc2c(-c3cccc(OC(F)(F)F)c3OC(F)(F)F)c3oc(=C(C#N)C#N)nc3c(-c3cccc(OC(F)(F)F)c3OC(F)(F)F)c2o1]

### Device Examples

### Device Example 1

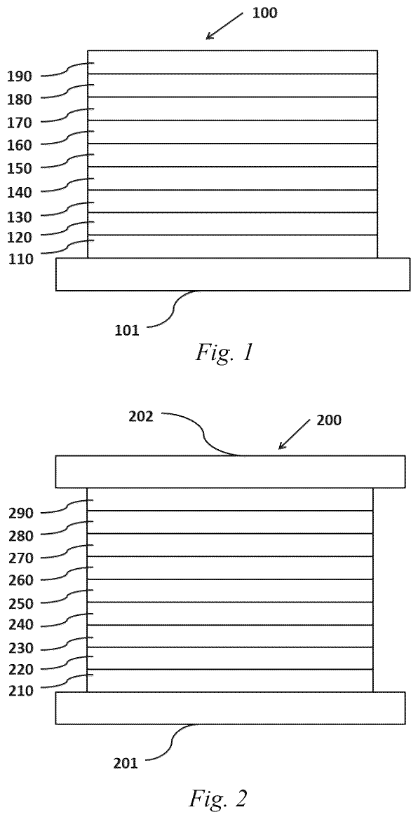

This example provided an organic electroluminescent device, see FIG. 1 for the structure thereof. If an encapsulation layer is added, reference can be made to the schematic diagram of FIG. 2. The preparation method therefor was as follows: an ITO substrate was patterned to achieve a light-emitting area of 2 mm×2 mm in size, followed by washing with isopropanol, UV, and ozone, respectively; subsequently, the ITO substrate was mounted on a substrate holder of a vacuum deposition device, and the pressure was adjusted to achieve a vacuum level of 1×10⁻⁷ torr. Firstly, on an ITO layer (anode) formed on the substrate, compound PD1 provided in Synthesis Example 1 of the present invention and compound HT-1 (the mass ratio of compound PD1 to compound HT-1 was 2:98) were deposited under vacuum to a thickness of 10 nm to form a hole injection layer; secondly, on the above-mentioned hole injection layer, compound HT-1 was deposited under vacuum to a thickness of 110 nm to form a hole transport layer; thirdly, on the above-mentioned hole transport layer, compound EB-1 was deposited under vacuum to a thickness of 10 nm to form an electron barrier layer; fourthly, on the above-mentioned electron barrier layer, a mixture of compound BD-1 and compound BH was deposited under vacuum to a thickness of 20 nm to form a light-emitting layer (the mass ratio of compound BD-1 to compound BH was 2:98); next, compound HB-1 was deposited under vacuum to a thickness of 5 nm to form a hole barrier layer; subsequently, on the above-mentioned hole barrier layer, compound ET-1 and Liq (the mass ratio of compound ET-1 to Liq was 5:5) was deposited under vacuum to a thickness of 30 nm to form an electron transport layer; then, on the above-mentioned electron transport layer, LiF was deposited under vacuum to a thickness of 1 nm to form an electron injection layer; and finally, on the above-mentioned electron injection layer, aluminum (Al) was deposited under vacuum to a thickness of 150 nm to form a cathode, thereby preparing the organic electroluminescent device.

Besides the material PD1 used in the present invention, the molecular structural formulas of the materials in the other layers of the device are as follows:

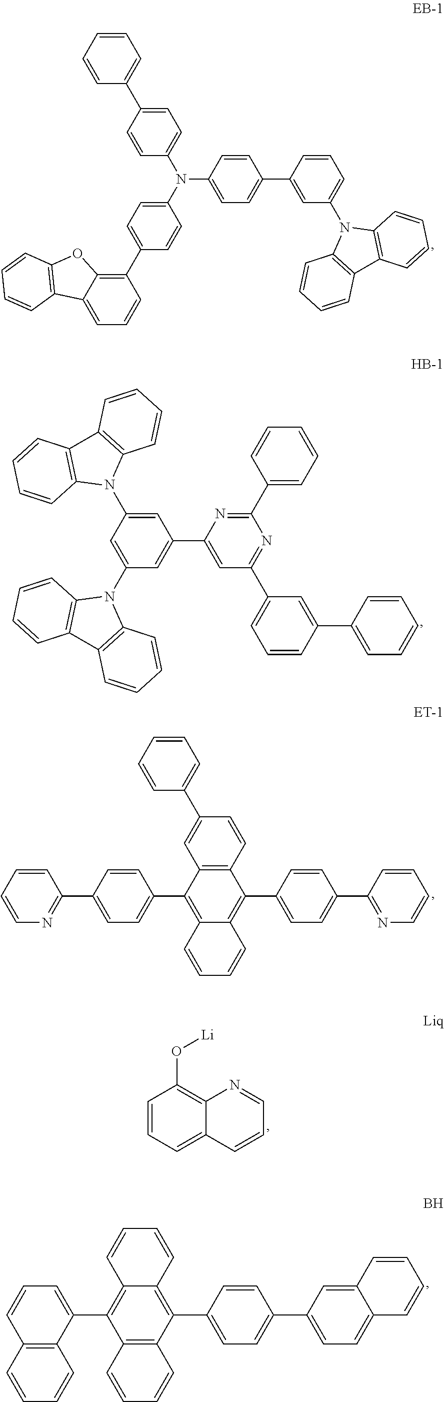

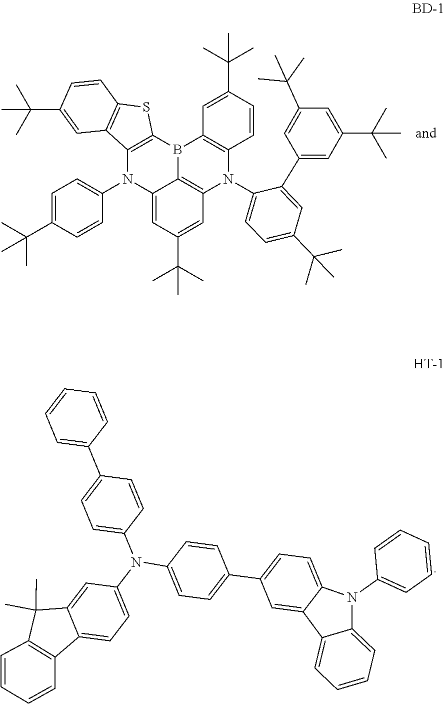 [SMILES: CC(C)(C)c1ccc(N2c3cc(C(C)(C)C)cc4c3B(c3cc(C(C)(C)C)ccc3N4c3ccc(C(C)(C)C)cc3-c3cc(C(C)(C)C)cc(C(C)(C)C)c3)c3sc4ccc(C(C)(C)C)cc4c32)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

The electrode preparation method and the deposition method for each functional layer in this embodiment were both conventional methods in the art, such as vacuum thermal evaporation or ink-jet printing. No more detailed description would be given here.

### Device Example 2

The preparation method was the same as that in Device Example 1, except that compound PD1 in the hole injection layer was replaced by compound PD2, and the mass ratio of compound PD2 to HT-1 in the hole injection layer was 2:98.

### Device Example 3

The preparation method was the same as that in Device Example 1, except that compound PD1 in the hole injection layer was replaced by compound PD3, and the mass ratio of compound PD3 to HT-1 in the hole injection layer was 2:98.

### Device Example 4

The preparation method was the same as that in Device Example 1, except that compound PD1 in the hole injection layer was replaced by compound PD4, and the mass ratio of compound PD4 to HT-1 in the hole injection layer was 2:98.

### Device Example 5

The preparation method was the same as that in Device Example 1, except that compound PD1 in the hole injection layer was replaced by compound PD5, and the mass ratio of compound PD5 to HT-1 in the hole injection layer was 2:98.

### Comparative Device Example 1

The preparation method was the same as that in Device Example 1, except that compound PD1 in the hole injection layer was replaced by compound RD-1, and the mass ratio of compound RD-1 to HT-1 in the hole injection layer was 2:98.

### Comparative Device Example 2

The preparation method was the same as that in Device Example 1, except that compound PD1 in the hole injection layer was replaced by compound RD-2, and the mass ratio of compound RD-2 to HT-1 in the hole injection layer was 2:98.

### Comparative Device Example 3

The preparation method was the same as that in Device Example 1, except that compound PD1 in the hole injection layer was replaced by compound RD-3, and the mass ratio of compound RD-3 to HT-1 in the hole injection layer was 2:98.

### Comparative Device Example 4

The preparation method was the same as that in Device Example 1, except that compound PD1 in the hole injection layer was replaced by compound RD-4, and the mass ratio of compound RD-4 to HT-1 in the hole injection layer was 2:98.

### Comparative Device Example 5

The preparation method was the same as that in Device Example 1, except that compound PD1 in the hole injection layer was replaced by compound RD-5, and the mass ratio of compound RD-5 to HT-1 in the hole injection layer was 2:98.

### Device Performance

The organic electroluminescent devices provided by Device Examples 1-5 and Comparative Device Examples 1-5 were tested by standard methods. For this purpose, the driving voltage and current efficiency (CE) of the organic electroluminescent device were determined at a current density of 10 mA/cm², while the lifetime (LT95) of the organic electroluminescent device was determined at a current density of J=25 mA/cm².

The test instruments and methods for testing the performance of the above OLED devices were as follows:
the brightness was tested by means of spectrum scanner PhotoResearch PR-635;
the current density and turn-on voltage were tested by digital SourceMeter Keithley 2400; and
lifetime test: on a silicon photoelectric OLED lifetime testing system was used.

The performance test results of the above devices were listed in Table 1.

TABLE 1
Device performance test results

| | | | | | Life- |
|---|---|---|---|---|---|
| | | | Driving | Current | time |
| | PD | Light | voltage | efficiency | LT95 |
| Device No. | material | color | (V) | CE (cd/A) | (h) |
| Device Example 1 | PD1 | Blue light | 3.91 | 6.74 | 86.9 |
| Device Example 2 | PD2 | Blue light | 3.86 | 6.90 | 87.4 |
| Device Example 3 | PD3 | Blue light | 3.73 | 6.98 | 89.2 |
| Device Example 4 | PD4 | Blue light | 3.93 | 6.69 | 86.5 |
| Device Example 5 | PD5 | Blue light | 3.75 | 6.95 | 89.3 |
| Comparative Device | RD-1 | Blue light | 3.96 | 6.64 | 86.2 |
| Example 1 | | | | | |
| Comparative Device | RD-2 | Blue light | 4.25 | 6.23 | 62.0 |
| Example 2 | | | | | |
| Comparative Device | RD-3 | Blue light | 4.15 | 5.73 | 65.6 |
| Example 3 | | | | | |
| Comparative Device | RD-4 | Blue light | 5.20 | 3.16 | 22.3 |
| Example 4 | | | | | |
| Comparative Device | RD-5 | Blue light | 5.26 | 3.30 | 25.4 |
| Example 5 | | | | | |

As can be seen from the device performance test results in Table 1 above:
the organic electroluminescent devices of Examples 1-5 prepared by the compounds provided by the present invention have lower driving voltage than Comparative Device Example 1 and also higher current efficiency and lifetime, indicating that the organic compounds of the present invention have superior hole injection ability as doping materials in the hole injection layer.

Compared with the organic electroluminescent devices provided from Comparative Device Examples 2 and 3, the driving voltages, current efficiencies, and lifetimes of the organic electroluminescent devices of Examples 1-5 prepared by using the organic compounds provided by the present invention are improved to different degrees. Compared with the organic electroluminescent device provided by Comparative Device Example 2, the driving voltages of the organic electroluminescent devices of Examples 1-5 prepared from the organic compounds provided by the present invention are reduced by 8.0% to 12.2%, the current efficiencies are increased by 7.4% to 12.0%, and the lifetimes are increased by 39.5% to 44.0%. Compared with the organic electroluminescent device provided by the Comparative Device Example 3, the driving voltages of the organic electroluminescent devices of Examples 1-5 prepared from the organic compounds provided by the present invention are reduced by 5.8% to 10.1%, the current efficiencies are increased by 16.8% to 21.8%, and the lifetimes are increased by 31.9% to 36.1%, indicating that the fluorobenzodioxole structure in the structures of the compounds of the present invention can better improve the doping ability of the material in the hole injection layer, leading to reduced voltage of the device and improved efficiency and lifetime of the device.

Compared with the organic electroluminescent devices provided by Comparative Device Examples 4 and 5, the driving voltages, current efficiencies, and lifetimes of the organic electroluminescent devices of Examples 1-5 prepared by using the organic compounds provided by the present invention are all significantly improved. Compared with the organic electroluminescent device provided by Comparative Device Example 4, the organic electroluminescent devices of Examples 1-5 prepared from the organic compounds provided by the present invention exhibit a reduction in driving voltage by 24.8% to 28.3%, an over two-fold improvement in current efficiency, and a three-fold increase in lifetime. Compared with the organic electroluminescent device provided by Comparative Device Example 5, the organic electroluminescent devices of Examples 1-5 prepared from the organic compounds provided by the present invention exhibit a reduction in driving voltage by 25.7% to 29.1%, a two-fold increase in current efficiency, and an approximately 2.5-fold increase in lifetime. The reason is speculated as follows: on the one hand, the compounds RD-4 and RD-5 of the comparative examples exhibit insufficient thermal stability, leading to decomposition during sublimation for device fabrication, which significantly deteriorates device performance; on the other hand, this also demonstrates the relatively good structural stability of the compound of the present invention and excellent device performance, so that it is a superior hole injection doping material.

By comparing Device Example 3 with Device Example 5, it can be seen that after replacing hydrogen with deuterium in the material, the device performance is not significantly changed. The hydrogens in the doping material of the hole injection layer can be replaced with deuterium without compromising the device performance.

### Stacked Device Example B1

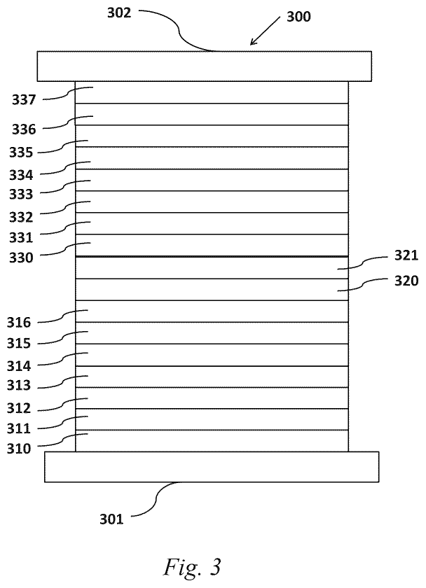

This example provided a tandem organic electroluminescent device, see FIG. 3 for the structure thereof. The preparation method therefor was as follows: an ITO substrate was patterned to achieve a light-emitting area of 2 mm×2 mm in size, followed by washing with isopropanol, UV, and ozone, respectively; subsequently, the ITO substrate was mounted on a substrate holder of a vacuum deposition device, and the pressure was adjusted to achieve a vacuum level of 1×10⁻⁷ torr. Firstly, on an ITO layer (anode) formed on the substrate, compound PD2 provided in the examples of the present invention and compound HT-1 (the mass ratio of compound PD2 to compound HT-1 was 2:98) were deposited under vacuum to a thickness of 10 nm to form a hole injection layer; secondly, on the above-mentioned hole injection layer, compound HT-1 was deposited under vacuum to a thickness of 25 nm to form a hole transport layer; thirdly, on the above-mentioned hole transport layer, compound EB-1 was deposited under vacuum to a thickness of 5 nm to form an electron barrier layer; fourthly, on the above-mentioned electron barrier layer, a mixture of compound BD-1 and compound BH was deposited under vacuum to a thickness of 20 nm to form a light-emitting layer (the mass ratio of compound BD-1 to compound BH was 2:98); next, on the above-mentioned light-emitting layer, compound HB-1 was deposited under vacuum to a thickness of 5 nm to form a hole barrier layer; subsequently, on the above-mentioned hole barrier layer, compound ET-1 and Liq (the mass ratio of ET-1 to Liq was 5:5) was deposited under vacuum to a thickness of 14 nm to form an electron transport layer; then, on the above-mentioned electron transport layer, compound N-CG and Yb (the mass ratio of compound N-CG to Yb was 99:1) was deposited to a thickness of 10 nm to form an n-type charge generation layer; next, on the above-mentioned n-type charge generation layer, compound PD2 provided in the examples of the present invention and compound HT-1 (the mass ratio of compound PD2 to compound HT-1 was 5:95) were deposited under vacuum to a thickness of 10 nm to form a p-type charge generation layer; next, on the above-mentioned p-type charge generation layer, compound HT-1 was deposited under vacuum to a thickness of 35 nm to form a second hole transport layer; next, on the above-mentioned second hole transport layer, compound EB-1 was deposited under vacuum to a thickness of 5 nm to form a second electron barrier layer; subsequently, on the above-mentioned second electron barrier layer, a mixture of compound BD-1 and compound BH was deposited under vacuum to a thickness of 20 nm to form a second light-emitting layer (the mass ratio of BD-1 to BH was 2:98); next, on the above-mentioned second light-emitting layer, compound HB-1 was deposited under vacuum to a thickness of 5 nm to form a second hole barrier layer; next, on the above-mentioned second hole barrier layer, compound ET-1 and Liq (the mass ratio of compound ET-1 to Liq was 5:5) were deposited under vacuum to a thickness of 30 nm to form a second electron transport layer; then, on the above-mentioned second electron transport layer, LiF was deposited to a thickness of 1 nm to form an electron injection layer; and finally, on the above-mentioned electron injection layer, aluminum (Al) was deposited to a thickness of 150 nm to form a cathode, thereby preparing the organic electroluminescent device.

Besides the material PD2 used in the present invention, the molecular structural formulas of the materials in the other layers of the device are as follows:

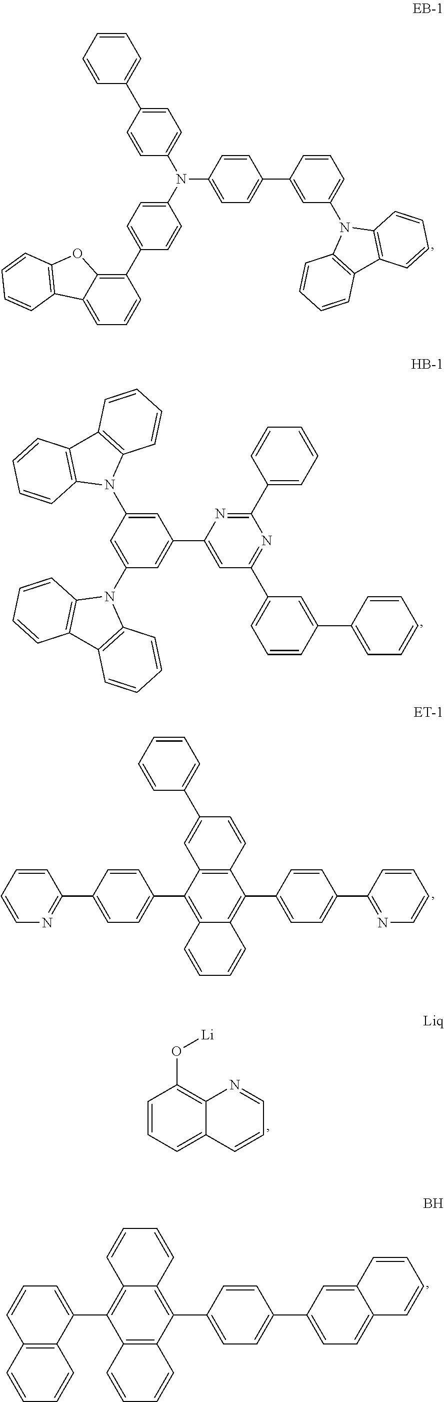

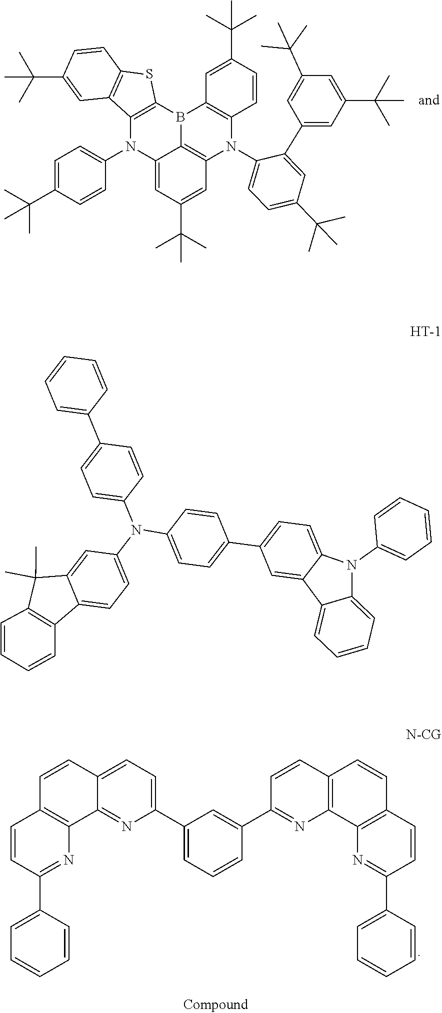 [SMILES: CC(C)(C)c1ccc(N2c3cc(C(C)(C)C)cc4c3B(c3cc(C(C)(C)C)ccc3N4c3ccc(C(C)(C)C)cc3-c3cc(C(C)(C)C)cc(C(C)(C)C)c3)c3sc4ccc(C(C)(C)C)cc4c32)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc3ccc4ccc(-c5cccc(-c6ccc7ccc8ccc(-c9ccccc9)nc8c7n6)c5)nc4c3n2)cc1]

### Stacked Device Example B2

The preparation method was the same as that in Stacked Device Example B1, except that compound PD2 in the p-type charge generation layer was replaced by compound PD3, and the mass ratio of compound PD3 to HT-1 in the p-type charge generation layer was 5:95.

### Comparative Stacked Device Example C1

The preparation method was the same as that in Stacked Device Example B1, except that compound PD2 in the p-type charge generation layer was replaced by compound RD-2, and the mass ratio of compound RD-2 to HT-1 in the p-type charge generation layer was 5:95.

### Stacked Device Performance

The organic electroluminescent devices provided by Stacked Device Examples B1 and B2 and Comparative Stacked Device Example C1 were tested by standard methods. For this purpose, the driving voltage and current efficiency (CE) of the organic electroluminescent device were determined at a current density of 10 mA/cm², while the lifetime (LT97) of the organic electroluminescent device was determined at a current density of J=35 mA/cm².

The test instruments and methods for testing the performance of the above OLED devices were as follows:
the brightness was tested by means of spectrum scanner PhotoResearch PR-635;
the current density and turn-on voltage were tested by digital SourceMeter Keithley 2400; and
lifetime test: on a silicon photoelectric OLED lifetime testing system was used.

The performance test results of the above devices were listed in Table 2.

TABLE 2
Device performance test results

| | | Driving | Current | Lifetime |
|---|---|---|---|---|
| | | voltage | efficiency | LT97 |
| Device No. | Light color | (V) | CE (cd/A) | (h) |
| Stacked Device Example | Blue light | 6.53 | 16.1 | 86.5 |
| B1 | | | | |
| Stacked Device Example | Blue light | 6.50 | 15.9 | 85.1 |
| B2 | | | | |
| Comparative Stacked | Blue light | 7.68 | 10.6 | 59.4 |
| Device Example C1 | | | | |

As can be seen from the device performance test results in Table 2 above:

Compared with the organic electroluminescent device provided by Comparative Stacked Device Example C1, the organic electroluminescent devices of Examples B1 and B2 prepared using the compounds provided by the present invention show a reduction in driving voltage by 15.0% and 15.4%, also a significant increase in current efficiency by 52% and 50%, and a significant increase in lifetime by 46% and 43%, indicating that compared with Comparative Example RD-2, the compounds provided by the present invention have superior doping ability and more excellent device performance when forming a p-type charge generation layer of a tandem organic electroluminescent device, so that the compound provided by the present invention is suitable as a material in the p-type charge generation layer of a stacked device.

In summary, the organic compounds provided by the present invention have superior doping ability for the hole injection layer, and the organic electroluminescent device prepared by using the organic compound of the present invention has excellent device performance and wide application value.

The above description is only preferred embodiments of the present invention, and the scope of protection of the present invention is not limited thereto. Any changes, substitutions, etc. readily conceivable to any of those familiar with the technical field within the technical scope of the disclosure of the present invention should be included in the scope of protection of the present invention. Therefore, for the scope of protection of the present invention, the scope of protection of the claims shall prevail.

1. A compound for an organic electroluminescent device, characterized in that the general structural formula of the compound is as represented by formula I: 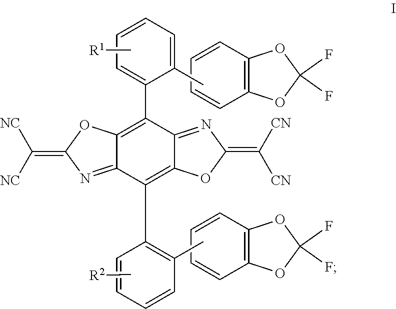
in formula I,
R¹ and R² respectively represent substituents on benzene rings and are selected from monosubstitution or polysubstitution, and when R¹ and R² refer to polysubstitution, the plurality of substituents can be the same or different;
R¹ and R² are, at each occurrence, each independently selected from any one of hydrogen, deuterium, fluoro, and CF₃; and
hydrogens in the compound represented by formula I can be each independently replaced by deuterium.

2. The compound according to claim 1, characterized in that the compound has a structure represented by formula I-1 or formula I-2: 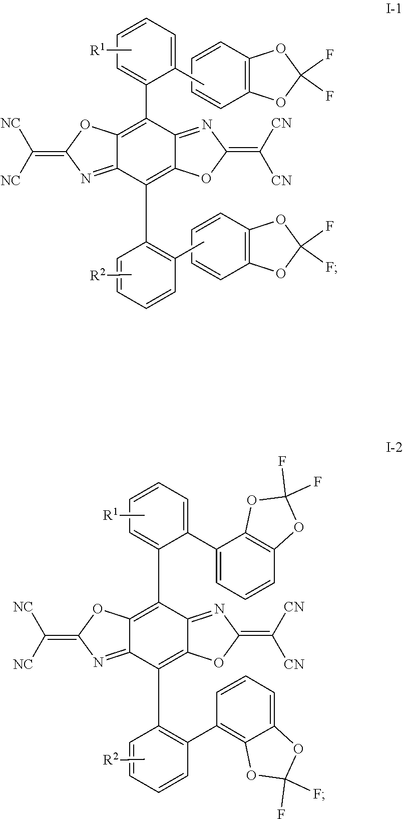
wherein
R¹ and R² respectively represent substituents on benzene rings and are selected from monosubstitution, polysubstitution, or unsubstitution, and when R¹ and R² refer to polysubstitution, the plurality of substituents can be the same or different;
R¹ and R² are, at each occurrence, each independently selected from any one of hydrogen, deuterium, fluoro, and CF₃; and
hydrogens in the compounds represented by formula I-1 and formula I-2 can be each independently replaced by deuterium.

3. The compound according to claim 1, characterized in that R¹ and R² represent the same group.

4. The compound according to claim 1, characterized in that the compound is selected from one of the following structures: 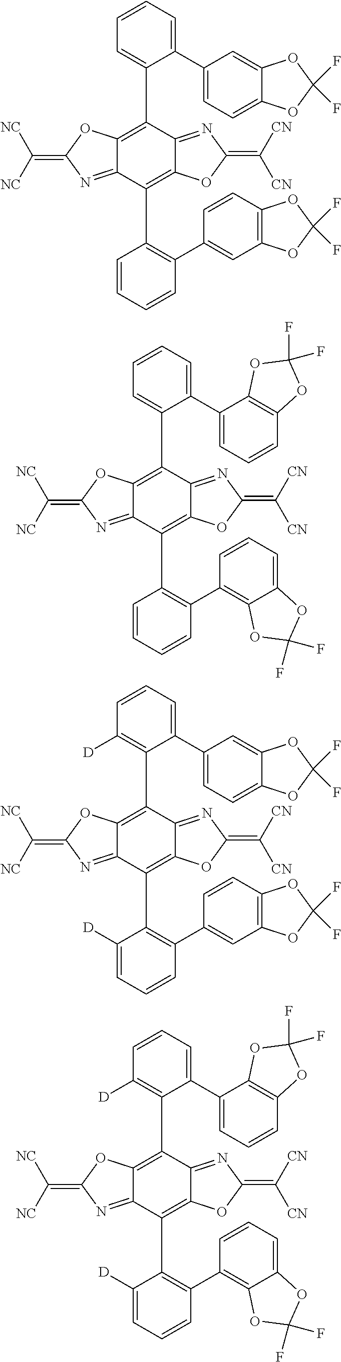 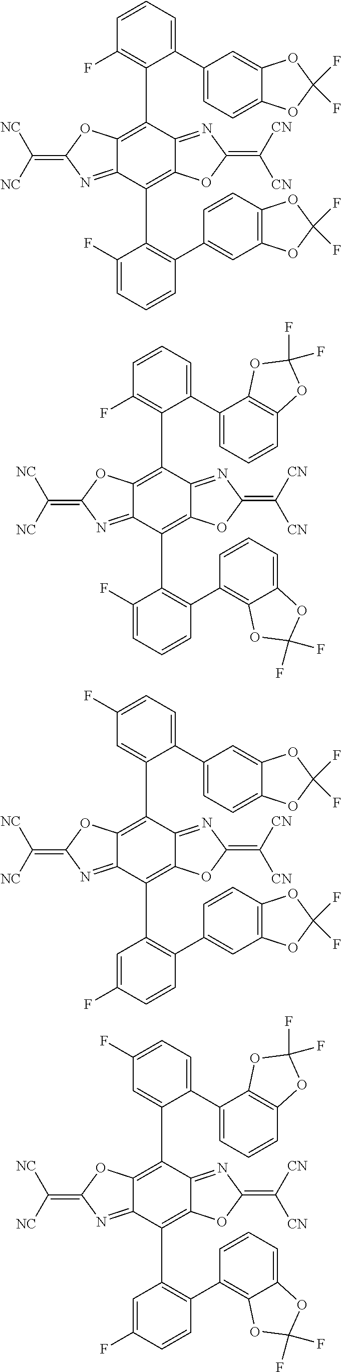 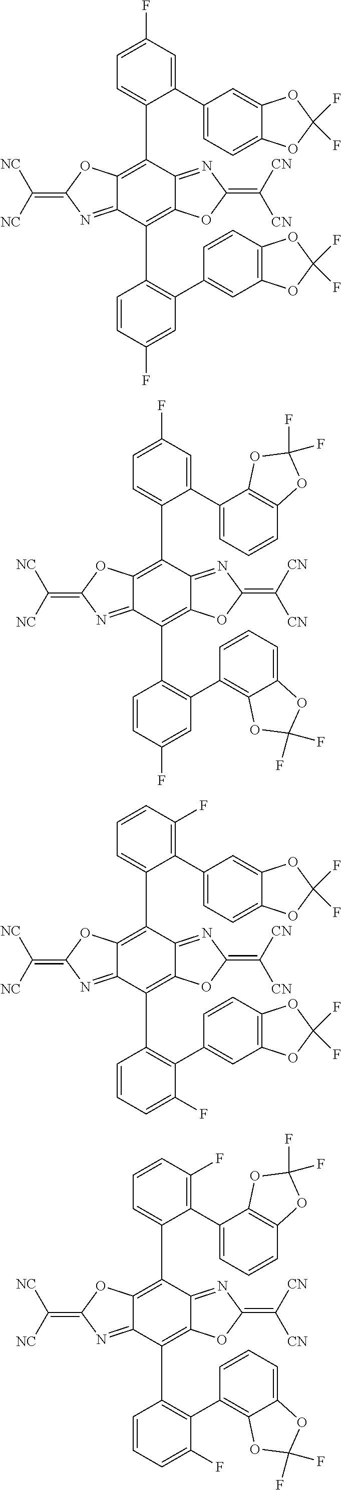 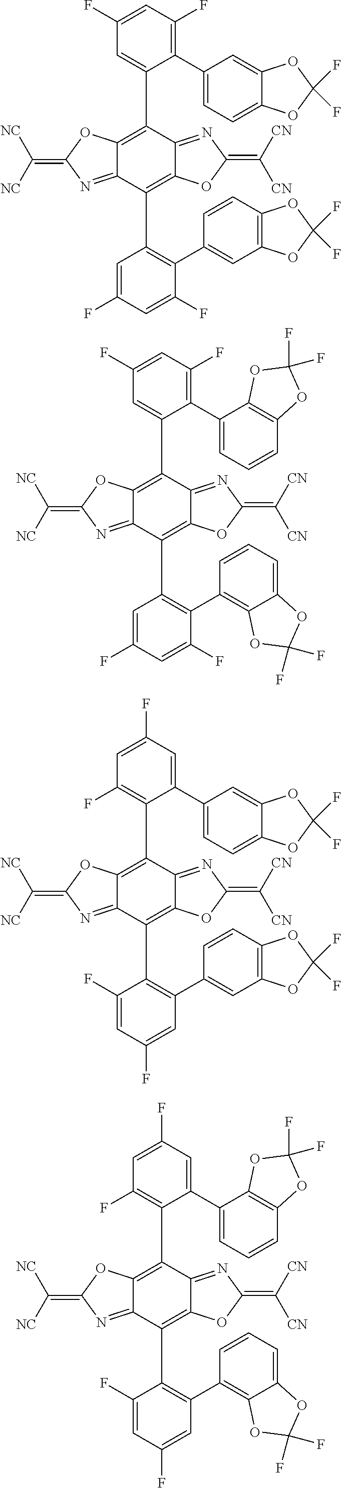 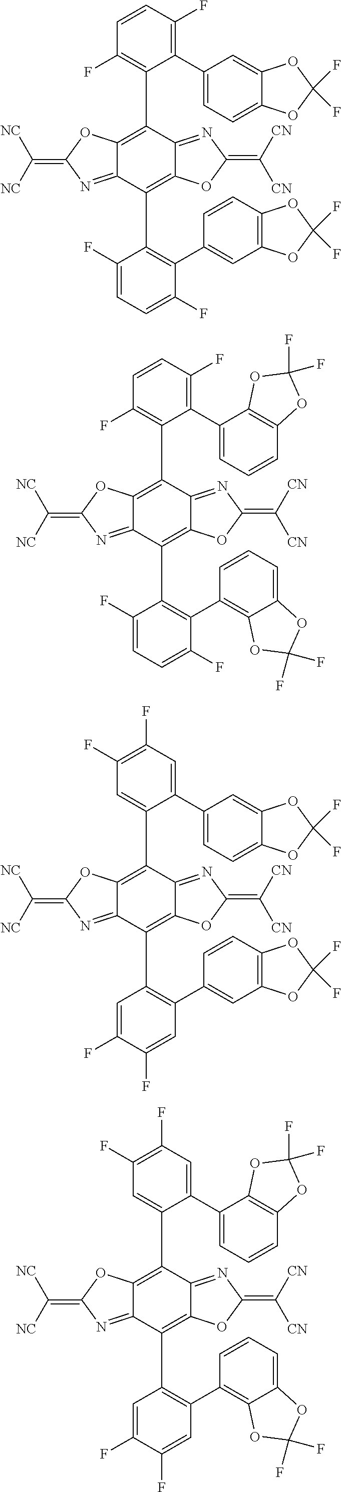 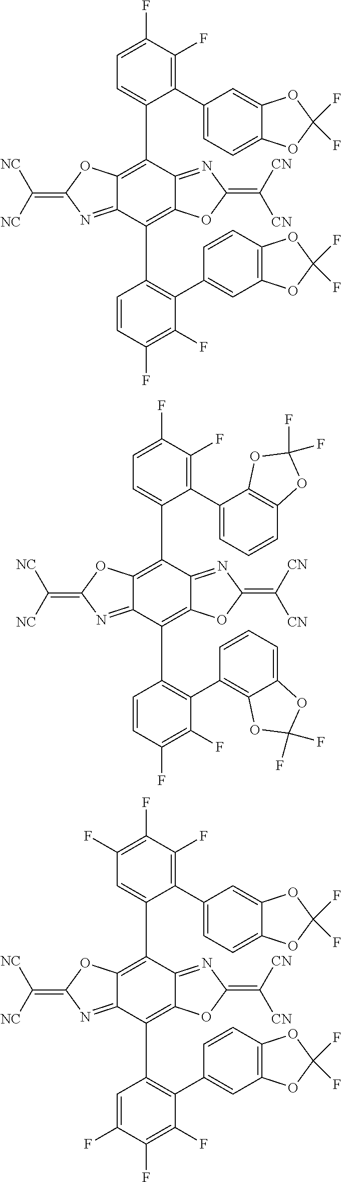 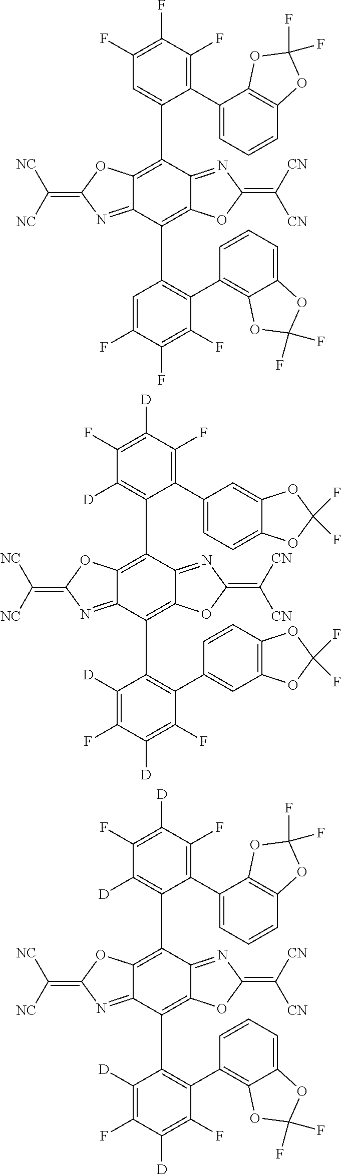 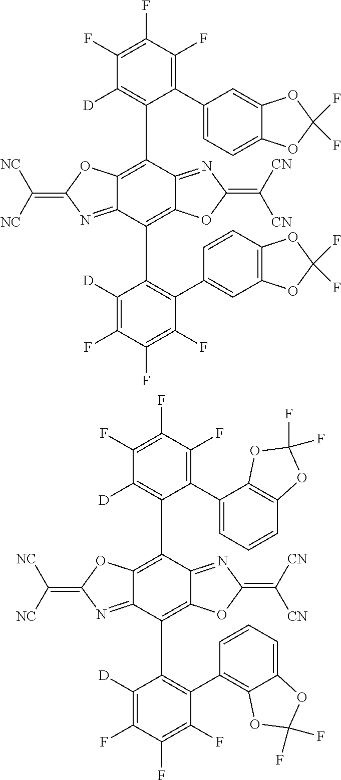 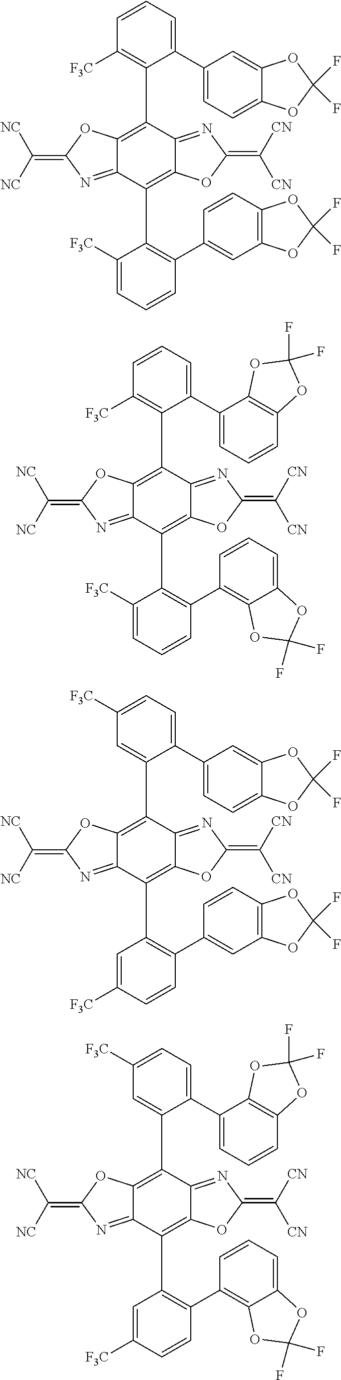 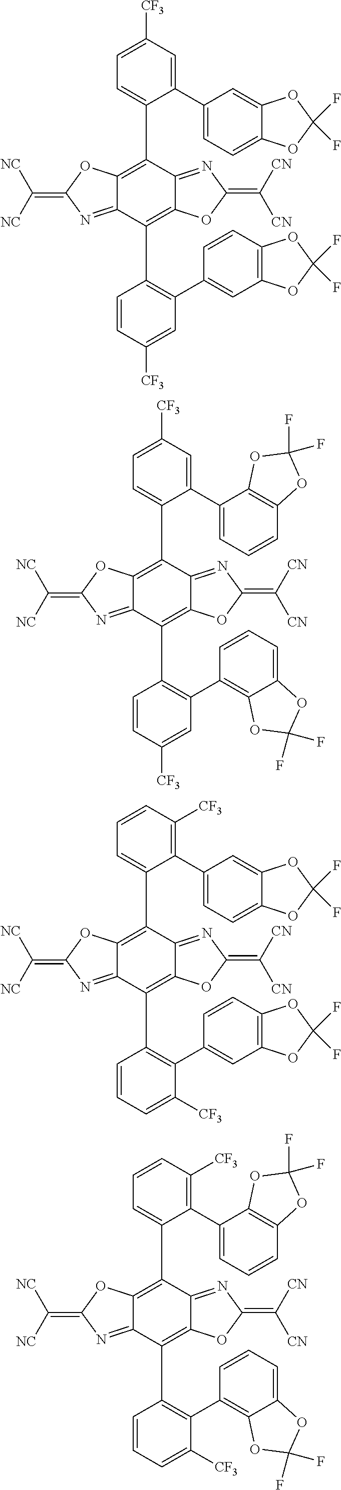 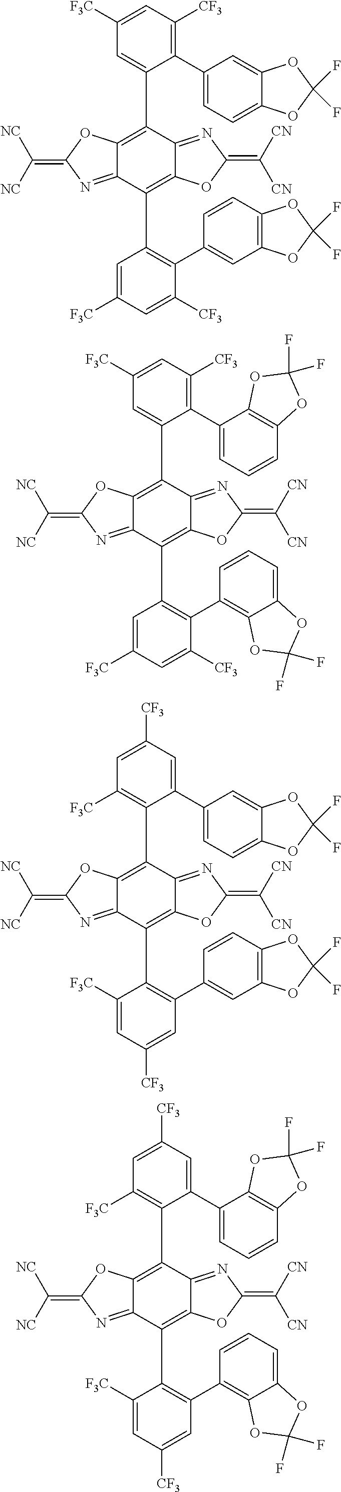 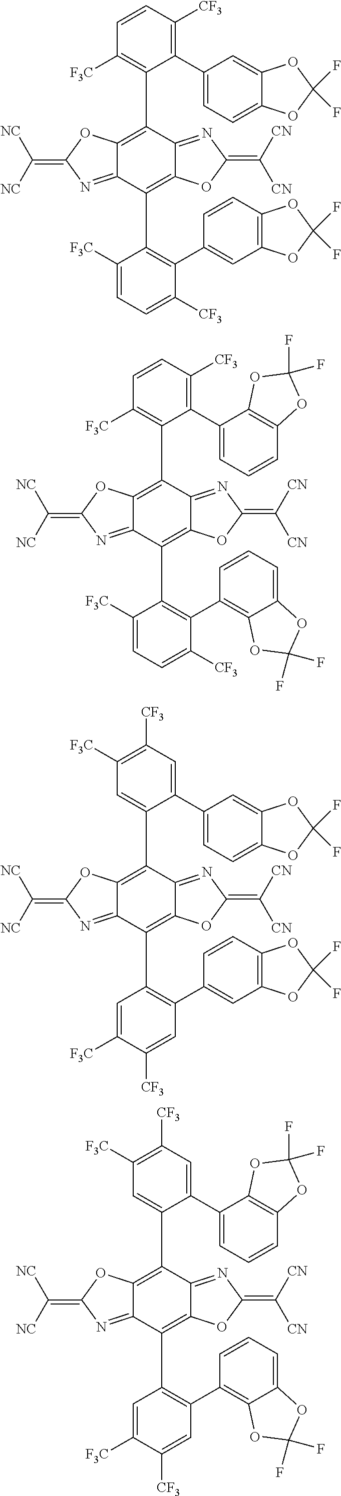 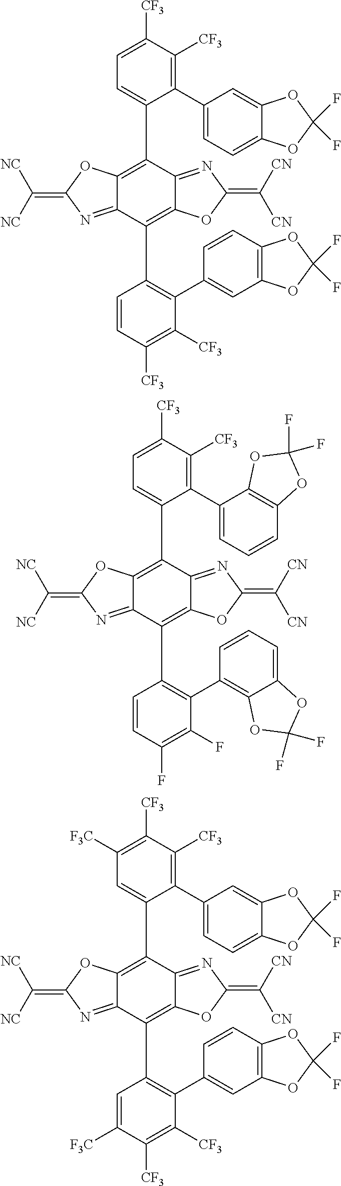 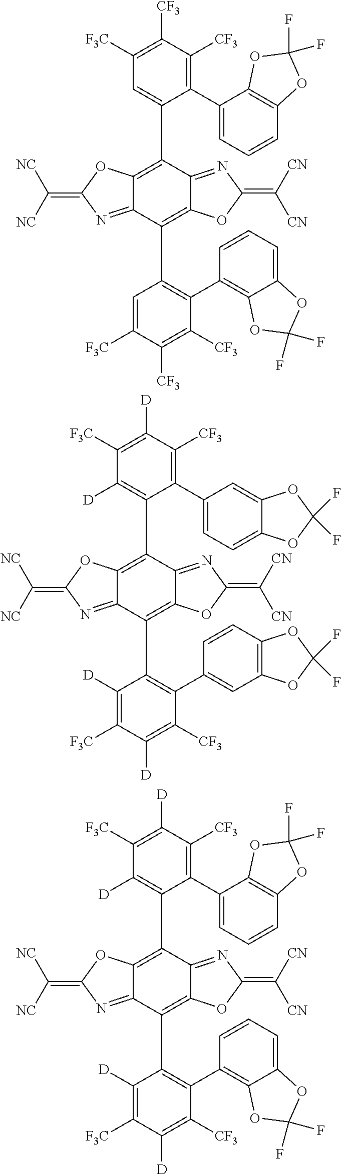 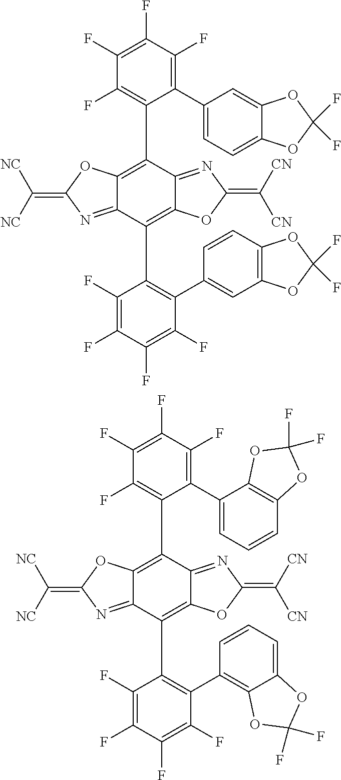 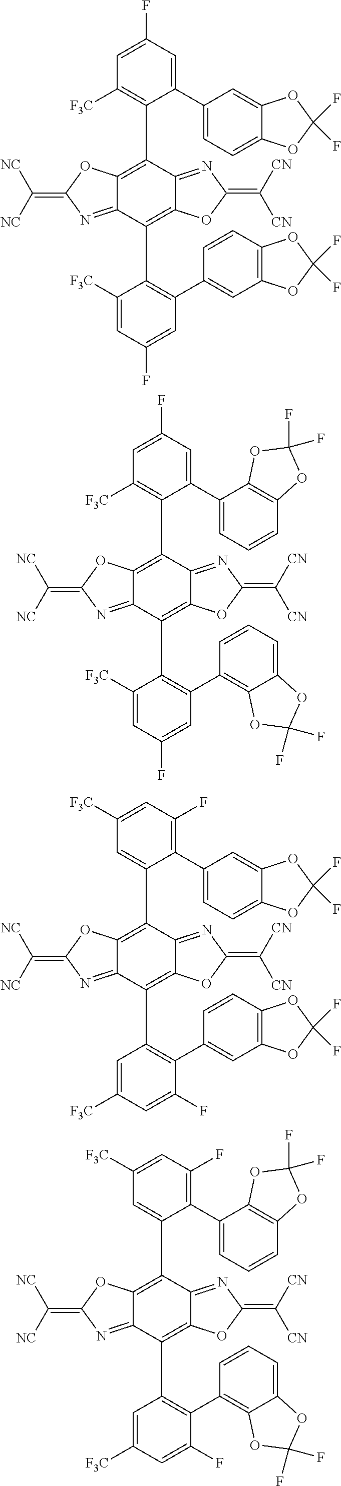 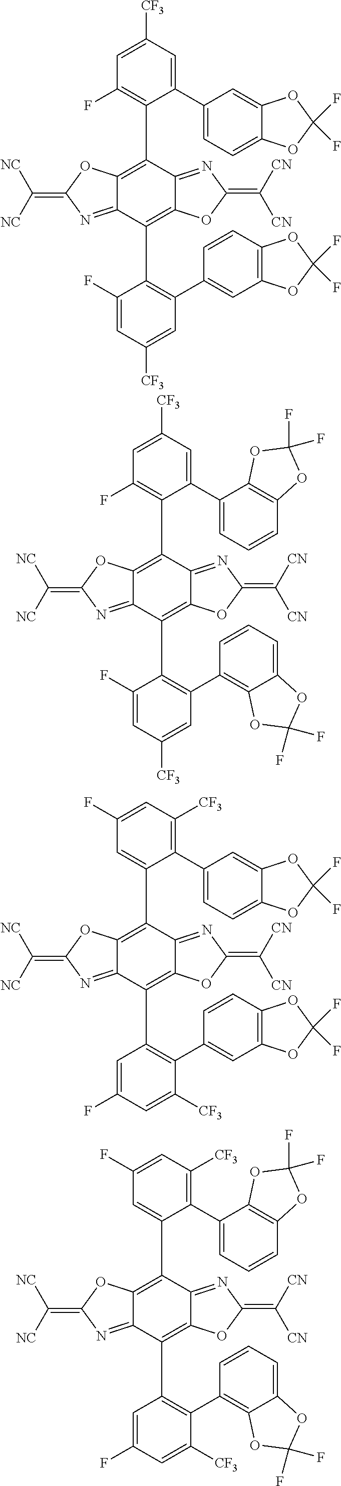 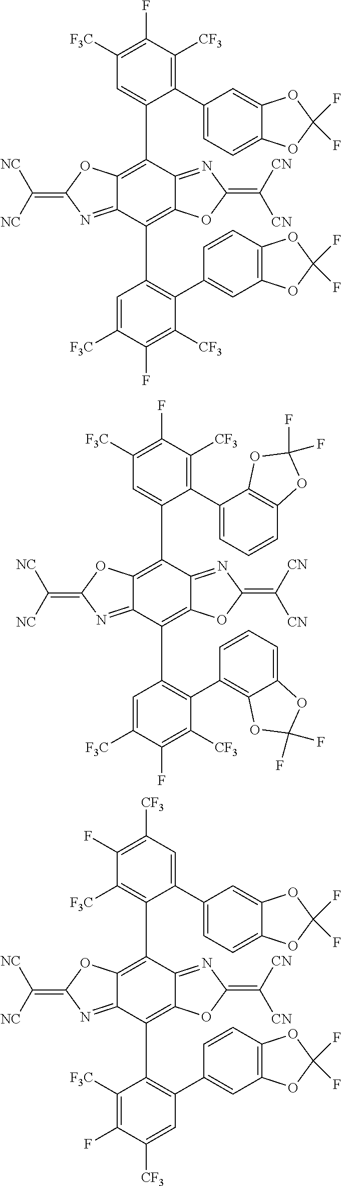 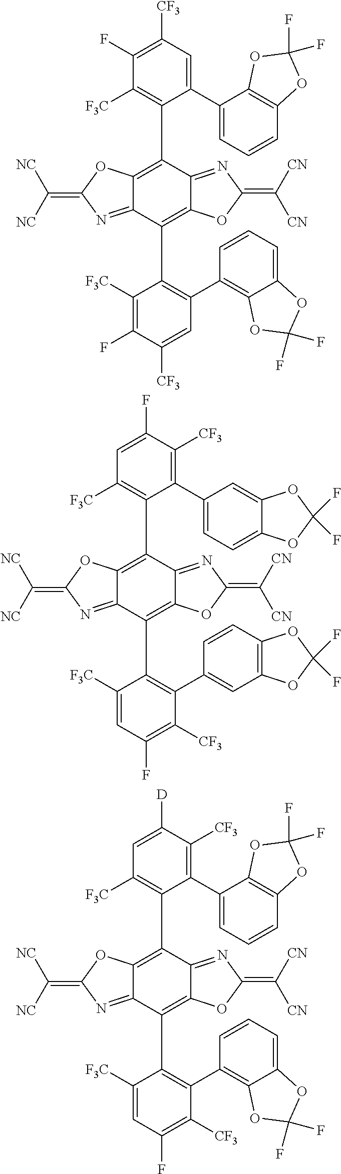 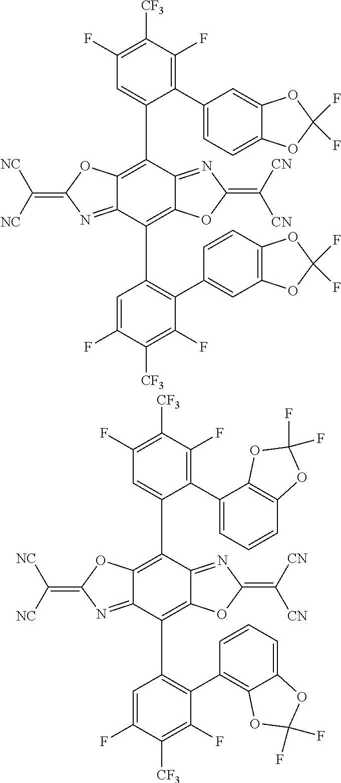 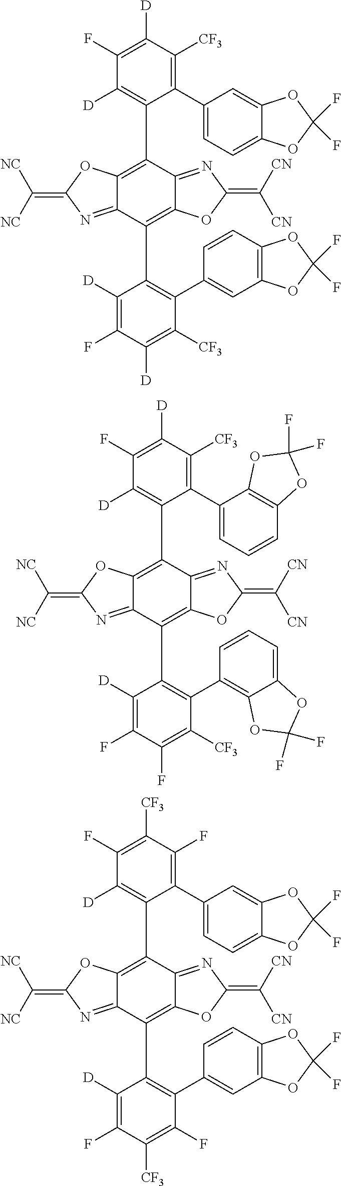 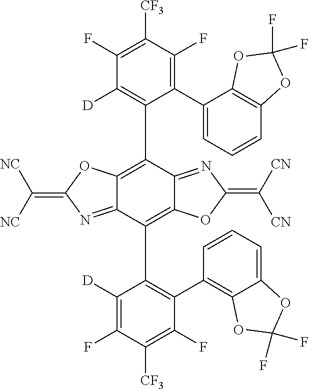 [SMILES: [2H]c1c(F)c(C(F)(F)F)c(F)c(-c2cccc3c2OC(F)(F)O3)c1-c1c2nc(=C(C#N)C#N)oc2c(-c2c([2H])c(F)c(C(F)(F)F)c(F)c2-c2cccc3c2OC(F)(F)O3)c2nc(=C(C#N)C#N)oc12]
hydrogens in each of the above compounds can be partially or completely replaced by deuterium.

5. An organic electroluminescent device, characterized by comprising:
an anode,
a cathode,
and an organic layer arranged between the anode and the cathode, wherein the organic layer comprises the compound according to claim 1.

6. The organic electroluminescent device according to claim 5, characterized in that the organic layer is a hole injection layer or a hole transport layer, and the hole injection layer or the hole transport layer is formed from the compound according to claim 1 alone.

7. The organic electroluminescent device according to claim 5, characterized in that the organic layer is a hole injection layer or a hole transport layer, and the hole injection layer or the hole transport layer comprises the compound according to claim 1 and at least one hole transport material.

8. The organic electroluminescent device of claim 5, characterized in that the organic electroluminescent device comprises at least two light-emitting units, and the organic layer is a charge generation layer arranged between the at least two light-emitting units, wherein the charge generation layer comprises a p-type charge generation layer and an n-type charge generation layer;
the p-type charge generation layer comprises the compound according to claim 1 and at least one hole transport material.

9. The organic electroluminescent device according to claim 8, characterized in that the charge generation layer further comprises a buffer layer arranged between the p-type charge generation layer and the n-type charge generation layer, and the buffer layer comprises the compound according to claim 1.

10. A display assembly, characterized by comprising the organic electroluminescent device according to claim 5.
